(19) United States
(12) Patent Application Publication
(10) Pub. No.: US 2025/0017049 A1
(43) Pub. Date: Jan. 9, 2025

(54) DISPLAY PANEL AND MANUFACTURING METHOD OF THE SAME

(71) Applicant: Samsung Display Co., Ltd., Yongin-si (KR)

(72) Inventors: HYEONSIK KIM, Yongin-si (KR); YOOLGUK KIM, Yongin-si (KR); JIYOON KIM, Yongin-si (KR); SANGHO LEE, Yongin-si (KR); HEEWOON IM, Yongin-si (KR)

(73) Assignee: Samsung Display Co., Ltd., Yongin-si (KR)

(21) Appl. No.: 18/634,151

(22) Filed: Apr. 12, 2024

(30) Foreign Application Priority Data
Jul. 5, 2023 (KR) 10-2023-0087161

(51) Int. Cl. H10K 59/122; H10K 39/34; H10K 59/12

(52) U.S. Cl. CPC H10K 59/122; H10K 39/34; H10K 59/1201

(57) ABSTRACT

Disclosed is a display panel which includes a base layer including a plurality of light emitting regions and a sensing region spaced apart from each other in a plan view, a plurality of light emitting elements that are disposed on the base layer and that overlap the plurality of light emitting regions, respectively, and a light sensing element that is disposed on the base layer and that overlaps the sensing region. The plurality of light emitting regions include a first light emitting region that emits light having a first wavelength, and at least a portion of the sensing region is surrounded by the first light emitting region in plan view.

### CROSS-REFERENCE TO RELATED APPLICATION(S)

This application claims priority to and benefits of Korean Patent Application No. 10-2023-0087161 under 35 U.S.C. § 119, filed on Jul. 5, 2023, in the Korean Intellectual Property Office, the entire contents of which are incorporated herein by reference.

### BACKGROUND

### 1. Technical Field

Embodiments relate to a display panel and a manufacturing method thereof, and more particularly, relate to a display panel for sensing a fingerprint and a method for manufacturing the display panel.

### 2. Description of the Related Art

A display device provides various functions that enable a user to interact with the display device. For example, the display device displays an image to provide information to the user, or may sense an input of the user. Recent display devices include a function for sensing information (e.g., biometric information) provided by the user. User information may be recognized by a capacitive sensing technique for sensing a change in capacitance between electrodes, a light sensing technique for sensing incident light using an optical sensor, or an ultrasonic sensing technique for sensing vibration using a piezoelectric element.

### SUMMARY

Embodiments provide a display panel including a sensor for sensing a fingerprint and a method for manufacturing the display panel.

However, embodiments are not limited to those set forth herein. The above and other embodiments will become more apparent to one of ordinary skill in the art to which the disclosure pertains by referencing the detailed description of the disclosure given below.

According to an embodiment, a display panel may include a base layer including a plurality of light emitting regions and a sensing region spaced apart from each other in plan view, a plurality of light emitting elements that are disposed on the base layer and that overlap the plurality of light emitting regions, respectively, and a light sensing element that is disposed on the base layer and that overlaps the sensing region. The plurality of light emitting regions include a first light emitting region that emits light having a first wavelength, and at least a portion of the sensing region may be surrounded by the first light emitting region in plan view.

In a first direction, the sensing region may be disposed between portions of the first light emitting region, and in a second direction intersecting the first direction, the sensing region may be adjacent to at least one side of the first light emitting region.

The sensing region may have a rectangular shape including sides that extend in a first direction and a second direction intersecting the first direction. The first light emitting region may surround at least three sides of the sensing region.

The plurality of light emitting regions may further include a second light emitting region that emits light having a second wavelength different from the first wavelength and a third light emitting region that emits light having a third wavelength different from the first wavelength and the second wavelength.

A sum of an area of the first light emitting region and an area of the sensing region may be substantially the same as an area of the second light emitting region.

A length of the first light emitting region in a direction may be greater than a length of the second light emitting region in the direction.

The first light emitting region may include a plurality of first light emitting regions, the second light emitting region may include a plurality of second light emitting regions, and the third light emitting region may include a plurality of third light emitting regions. The plurality of first light emitting regions may be arranged side by side in a direction, the plurality of second light emitting regions may be arranged side by side in the direction, and the plurality of third light emitting regions may be arranged side by side in the direction.

An area of the sensing region may be smaller than an area of the first light emitting region.

The sensing region may include a first side and a second side that extend in a first direction and a third side and a fourth side that extend in a second direction intersecting the first direction. The first light emitting region may surround the first side, the third side, and the fourth side, and may not surround at least a portion of the second side.

The light having the first wavelength may be light having a green wavelength range.

The light having the first wavelength may be light having a red wavelength range.

The display panel may further include a pixel defining layer that is disposed on the base layer and that has a plurality of openings. The plurality of openings may define the plurality of light emitting regions and the sensing region, respectively.

The pixel defining layer may include a barrier wall portion disposed on the base layer and a liquid-repellent portion that is disposed on the barrier wall portion and that includes a liquid-repellent organic material.

The pixel defining layer may include a first pixel defining portion disposed between the plurality of light emitting regions and a second pixel defining portion disposed between the first light emitting region and the sensing region. A height of the second pixel defining portion may be smaller than a height of the first pixel defining portion.

The plurality of light emitting elements may include a first light emitting element that overlaps the first light emitting region. The first light emitting element may include a first light emitting electrode disposed on the base layer, a second light emitting electrode disposed over the first light emitting electrode, and a first functional layer disposed between the first light emitting electrode and the second light emitting electrode. The light sensing element may include a first light sensing electrode disposed on the base layer, a second light sensing electrode disposed over the first light sensing electrode, and a second functional layer disposed between the first light sensing electrode and the second light sensing electrode. The first functional layer and the second functional layer may include a same material.

According to an embodiment, a display panel may include a base layer including a first light emitting region and a sensing region spaced apart from each other in plan view, a pixel defining layer that is disposed on the base layer and that has a first opening that defines the first light emitting region and a second opening that defines the sensing region, a first light emitting element disposed on the base layer and disposed in the first opening, and a light sensing element disposed on the base layer and disposed in the second opening. At least a portion of the second opening may be surrounded by the first opening in plan view.

According to an embodiment, a method for manufacturing a display panel may include preparing a preliminary display panel including a base layer and a pixel defining layer disposed on the base layer and forming a first light emitting element and a light sensing element by providing an organic material on the preliminary display panel. The pixel defining layer has a first opening and a second opening. The first opening may define a first light emitting region in which the first light emitting element is disposed, and the second opening may define a sensing region in which the light sensing element is disposed. At least a portion of the second opening may be surrounded by the first opening in plan view.

The first light emitting element may include a first functional layer, and the light sensing element may include a second functional layer. The first functional layer and the second functional layer may be formed by a same process.

Forming each of the first functional layer and the second functional layer may include providing the organic material in the second opening.

The pixel defining layer may include a first pixel defining portion adjacent to the first opening and spaced apart from the second opening and a second pixel defining portion disposed between the first opening and the second opening. A height of the second pixel defining portion may be smaller than a height of the first pixel defining portion.

### BRIEF DESCRIPTION OF THE DRAWINGS

The above and other objects and features of the disclosure will become apparent by describing in detail embodiments thereof with reference to the accompanying drawings.

FIG. 1 is a schematic perspective view of a display device according to an embodiment.

FIG. 2 is a schematic block diagram of the display device according to an embodiment.

FIG. 3 is a schematic block diagram of a display layer and a display driver according to an embodiment.

FIG. 4 illustrates a schematic diagram of an equivalent circuit of a pixel and a schematic diagram of an equivalent circuit of a sensor according to an embodiment.

FIG. 5 is a schematic sectional view of a display panel according to an embodiment.

FIG. 6 is a schematic plan view illustrating a portion of a display region of the display panel according to an embodiment.

FIGS. 7A and 7B are enlarged schematic plan views illustrating portions of the display region of the display panel according to embodiments.

FIGS. 8 and 9 are schematic sectional views of a portion of the display region of the display panel.

FIG. 10 is a schematic sectional view of a portion of the display region of the display panel.

FIGS. 11 and 12 are enlarged schematic plan views illustrating portions of the display region of the display panel according to embodiments.

FIG. 13 is a flowchart illustrating a display panel manufacturing method according to an embodiment.

FIGS. 14A, 14B, 14C, 14D, 14E, and 14F are schematic sectional views illustrating steps of the display panel manufacturing method according to an embodiment.

FIGS. 15A, 15B, and 15C are schematic sectional views illustrating steps of a display panel manufacturing method according to an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

Unless otherwise defined, all terms used herein, including technical or scientific terms, have the same meanings as those generally understood by those skilled in the art to which the disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the present application.

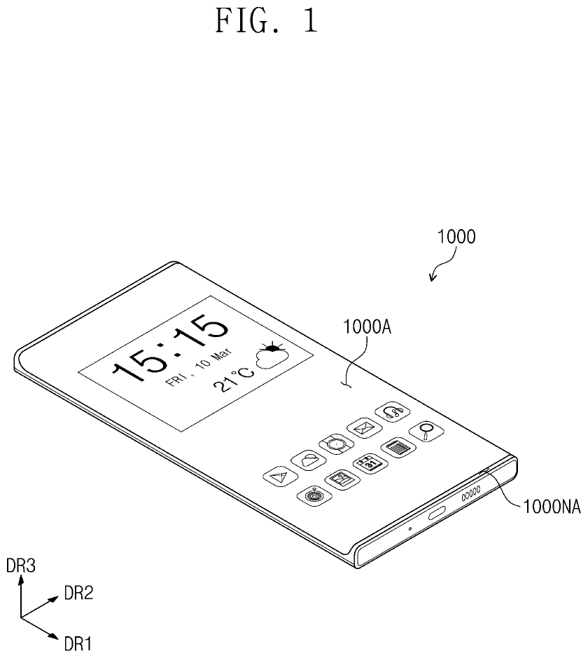

FIG. 1 is a schematic perspective view of a display device 1000 according to an embodiment.

Referring to FIG. 1, the display device 1000 may be activated based on an electrical signal. For example, the display device 1000 may be a mobile phone, a foldable mobile phone, a notebook computer, a television, a tablet computer, a car navigation unit, a game machine, or a wearable device, but embodiments are not limited thereto. In FIG. 1, the display device 1000 is illustrated as a mobile phone.

The display device 1000 may include an active region 1000A and a peripheral region 1000NA. The display device 1000 may display an image through the active region 1000A. The active region 1000A may include a plane defined by a first direction DR1 and a second direction DR2. The peripheral region 1000NA may surround the periphery of the active region 1000A.

A thickness direction of the display device 1000 may be parallel to a third direction DR3 intersecting the first direction DR1 and the second direction DR2. Accordingly, front surfaces (or upper surfaces) and rear surfaces (or lower surfaces) of members (or elements) constituting the display device 1000 may be defined based on the third direction DR3.

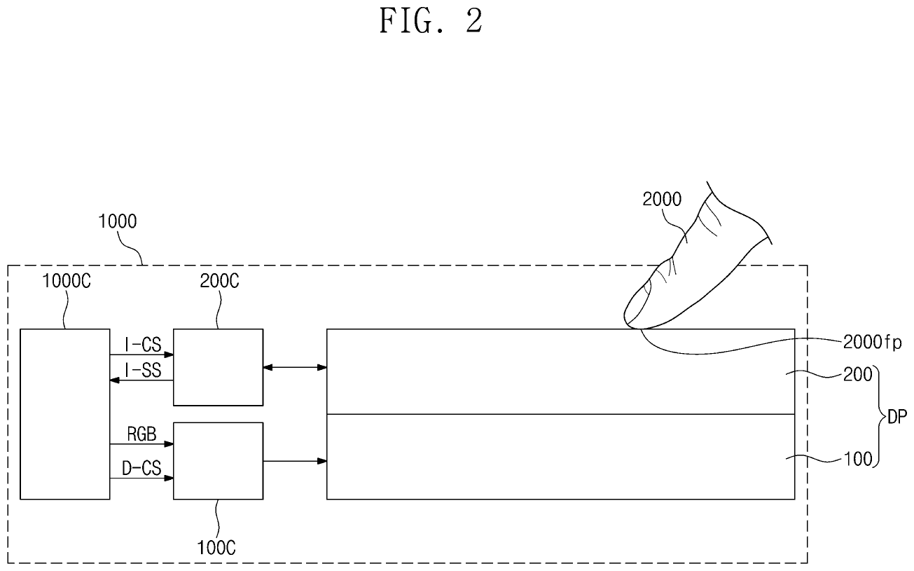

FIG. 2 is a schematic block diagram of the display device 1000 according to an embodiment.

Referring to FIG. 2, the display device 1000 may include a display panel DP, a display driver 100C, a sensor driver 200C, and a main driver 1000C. The display panel DP may include a display layer 100 and a sensor layer 200 disposed on the display layer 100. In another example, the sensor layer 200 may be omitted.

The display layer 100 may be a component that substantially displays an image. The display layer 100 may be an emissive display layer. For example, the display layer 100 may be an organic light emitting display layer, an inorganic light emitting display layer, an organic-inorganic light emitting display layer, a quantum-dot display layer, a micro-LED display layer, or a nano-LED display layer. For example, the display layer 100 may include a sensor that senses (or reacts to) light reflected by a fingerprint 2000fp of a user.

The sensor layer 200 may be disposed on the display layer 100. The sensor layer 200 may sense an external input 2000 applied from the outside. The external input 2000 may include all input means capable of providing (or causing) a change in capacitance. For example, the sensor layer 200 may sense not only an input by a passive-type input means (e.g., the user's body), but also an input by an active-type input means that provides a drive signal.

The main driver 1000C may control overall operation of the display device 1000. For example, the main driver 1000C may control operations of the display driver 100C and the sensor driver 200C. The main driver 1000c may include at least one microprocessor, and may further include a graphic controller. The main driver 1000c may be referred to as an application processor, a central processing unit, or a main processor.

The display driver 100C may drive the display layer 100. The display driver 100C may receive image data RGB and a control signal D-CS from the main driver 1000C. The control signal D-CS may include various signals. For example, the control signal D-CS may include an input vertical synchronization signal, an input horizontal synchronization signal, a main clock, a data enable signal, and the like. Based on the control signal D-CS, the display driver 100C may generate a vertical synchronization signal and a horizontal synchronization signal for controlling timing at which a signal is provided to the display layer 100.

The sensor driver 200C may drive the sensor layer 200. The sensor driver 200C may receive a control signal I-CS from the main driver 1000C. The control signal I-CS may include a mode determination signal for determining a drive mode of the sensor driver 200C and a clock signal.

The sensor driver 200C may calculate coordinate information of an input based on a signal received from the sensor layer 200, and may provide a coordinate signal I-SS having the coordinate information to the main driver 1000C. The main driver 1000C may execute an operation corresponding to a user input, based on the coordinate signal I-SS. For example, the main driver 1000C may operate the display driver 100C such that a new application image may be displayed on the display layer 100.

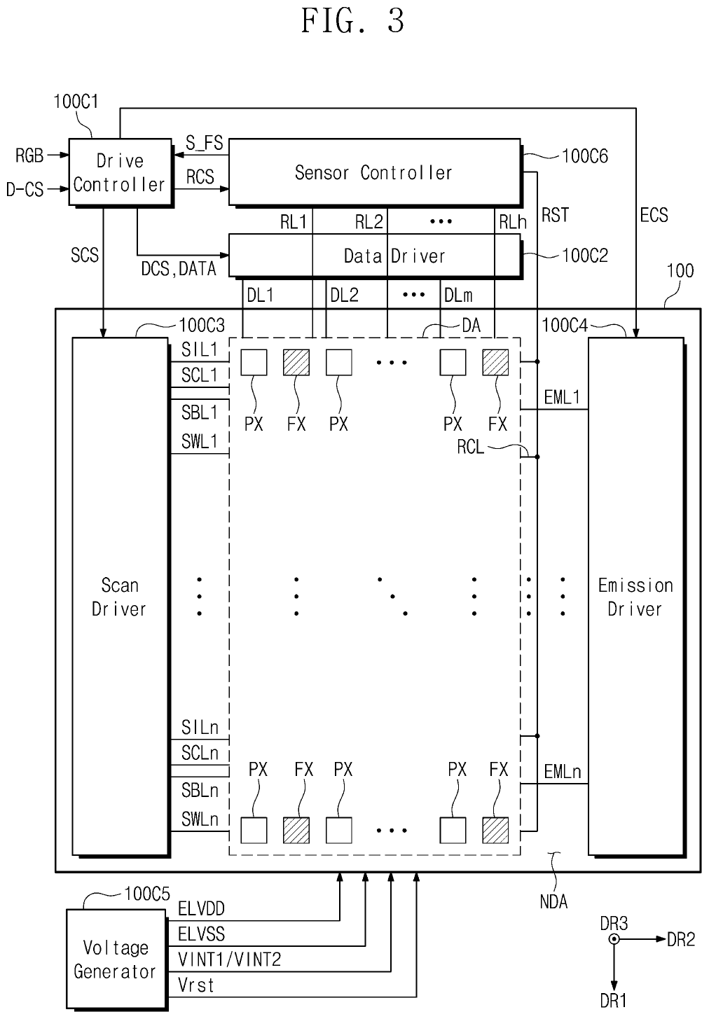

FIG. 3 is a schematic block diagram of the display layer and the display driver according to an embodiment.

Referring to FIGS. 2 and 3, the display driver 100C may include a drive controller 100C1, a data driver 100C2, a scan driver 100C3, an emission driver 100C4, a voltage generator 100C5, and a sensor controller 100C6.

The display layer 100 may include an active region DA (or a display region) corresponding to the active region 1000A (refer to FIG. 1) and a peripheral region NDA (or a non-display region) corresponding to the peripheral region 1000NA (refer to FIG. 1).

The display layer 100 may include pixels PX disposed in the active region DA and sensors FX disposed in the active region DA. The display layer 100 may further include initialization scan lines SIL1 to SILn, compensation scan lines SCL1 to SCLn, write scan lines SWL1 to SWLn, black scan lines SBL1 to SBLn, emission control lines EML1 to EMLn, data lines DLI to DLm, and readout lines RL1 to RLh.

The initialization scan lines SIL1 to SILn, the compensation scan lines SCL1 to SCLn, the write scan lines SWL1 to SWLn, the black scan lines SBL1 to SBLn, and the emission control lines EML1 to EMLn may extend in the second direction DR2. The initialization scan lines SIL1 to SILn, the compensation scan lines SCL1 to SCLn, the write scan lines SWL1 to SWLn, the black scan lines SBL1 to SBLn, and the emission control lines EML1 to EMLn may be arranged in the first direction DR1 so as to be spaced apart from each other. The data lines DLI to DLm and the readout lines RL1 to RLh may extend in the first direction DR1, and may be arranged in the second direction DR2 so as to be spaced apart from each other.

The pixels PX may be electrically connected to the initialization scan lines SIL1 to SILn, the compensation scan lines SCL1 to SCLn, the write scan lines SWL1 to SWLn, the black scan lines SBL1 to SBLn, the emission control lines EML1 to EMLn, and the data lines DLI to DLm, respectively. For example, each of the pixels PX may be electrically connected to four scan lines. However, embodiments are not limited thereto, the number of scan lines connected to each pixel PX may be changed.

The sensors FX may be electrically connected to the readout lines RL1 to RLh. A sensor (e.g., single sensor) FX may be electrically connected to a scan line (e.g., single scan line), for example, a write scan line (e.g., single write scan line) among the write scan lines SWL1 to SWLn. However, embodiments are not limited thereto. The number of scan lines connected to each sensor FX may be varied.

In an embodiment, the number of readout lines RL1 to RLh may correspond to half of the number of data lines DLI to DLm. However, embodiments are not limited thereto. In another example, the number of readout lines RL1 to RLh may correspond to ¼ or ⅛ of the number of data lines DLI to DLm, or may be equal to the number of data lines DLI to DLm.

The drive controller 100C1 may receive the image data RGB and the control signal D-CS. The drive controller 100C1 may generate an image data signal DATA by converting the data format of the image data RGB according to the specification of an interface with the data driver 100C2. The drive controller 100C1 may output a first control signal SCS, a second control signal ECS, a third control signal DCS, and a fourth control signal RCS.

The data driver 100C2 may receive the third control signal DCS and the image data signal DATA from the drive controller 100C1. The data driver 100C2 may convert the image data signal DATA into data signals, and may output the data signals to the data lines DLI to DLm to be described below. The data signals may be analog voltages corresponding to gray level values of the image data signal DATA.

The scan driver 100C3 may receive the first control signal SCS from the drive controller 100C1. The scan driver 100C3 may output scan signals to the scan lines in response to the first control signal SCS. For example, in response to the first control signal SCS, the scan driver 100C3 may output initialization scan signals to the initialization scan lines SIL1 to SILn, and may output compensation scan signals to the compensation scan lines SCL1 to SCLn. For example, in response to the first control signal SCS, the scan driver 100C3 may output write scan signals to the write scan lines SWL1 to SWLn, and may output black scan signals to the black scan lines SBL1 to SBLn.

The emission driver 100C4 may receive the second control signal ECS from the drive controller 100C1. The emission driver 100C4 may output emission control signals to the emission control lines EML1 to EMLn in response to the second control signal ECS. In another example, the scan driver 100C3 may be connected to the emission control lines EML1 to EMLn. Thus, the emission driver 100C4 may be omitted, and the scan driver 100C3 may output emission control signals to the emission control lines EML1 to EMLn.

The scan driver 100C3 and the emission driver 100C4 may be disposed in the peripheral region NDA of the display layer 100. However, embodiments are not limited thereto. For example, at least a portion of the scan driver 100C3 and at least a portion of the emission driver 100C4 may be disposed in the active region DA.

The voltage generator 100C5 may generate voltages required for an operation of the display layer 100. In an embodiment, the voltage generator 100C5 may generate a first drive voltage ELVDD, a second drive voltage ELVSS, a first initialization voltage VINT1, a second initialization voltage VINT2, and a reset voltage Vrst.

The sensor controller 100C6 may receive the fourth control signal RCS from the drive controller 100C1.

In response to the fourth control signal RCS, the sensor controller 100C6 may receive detection signals from the readout lines RL1 to RLh. The sensor controller 100C6 may process the detection signals received from the readout lines RL1 to RLh, and may provide processed detection signals S_FS to the drive controller 100C1.

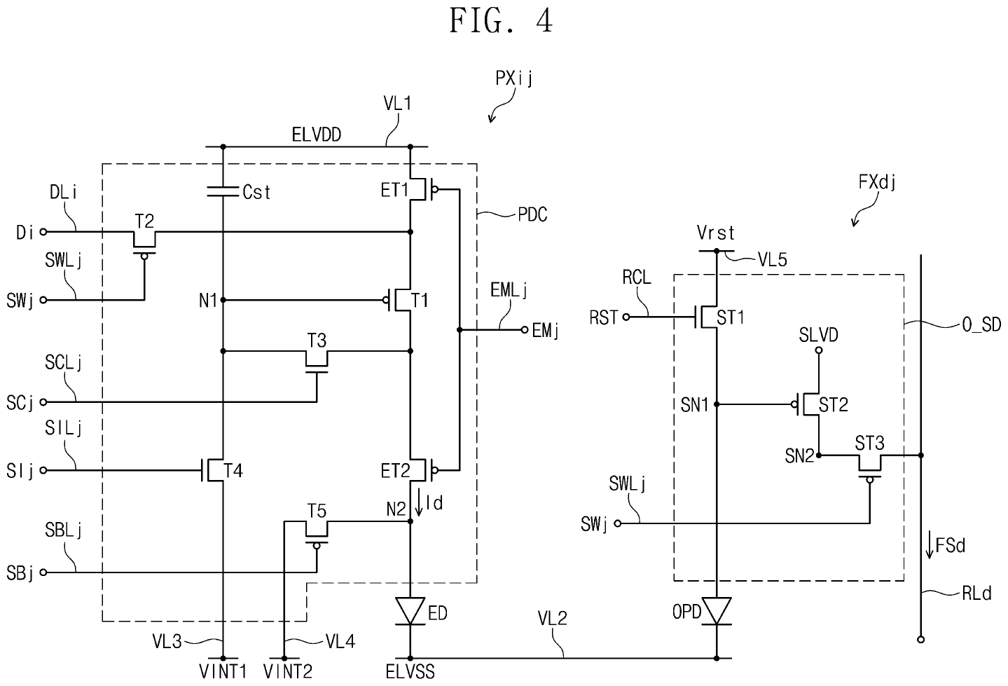

FIG. 4 illustrates a schematic diagram of an equivalent circuit of a pixel and a schematic diagram of an equivalent circuit of a sensor according to an embodiment.

In FIG. 4, the equivalent circuit of a pixel PXij among the pixels PX (refer to FIG. 3) is illustrated. The pixels PX may have the same circuit structure. Therefore, description of the circuit structure for the pixel PXij may be applied to the remaining pixels PX, and detailed description of the remaining pixels PX will be omitted for descriptive convenience. For example, in FIG. 4, an equivalent circuit of a sensor (e.g., single sensor) FXdj among the sensors FX illustrated in FIG. 3 is illustrated. The sensors FX have the same circuit structure. Therefore, description of the circuit structure for the sensor FXdj may be applied to the remaining sensors FX, and detailed description of the remaining sensors FX will be omitted for descriptive convenience.

Referring to FIGS. 3 and 4, the pixel PXij may be connected to the i-th data line DLi among the data lines DLI to DLm, the j-th initialization scan line SILj among the initialization scan lines SIL1 to SILn, the j-th compensation scan line SCLj among the compensation scan lines SCL1 to SCLn, the j-th write scan line SWLj among the write scan lines SWL1 to SWLn, the j-th black scan line SBLj among the black scan lines SBL1 to SBLn, and the j-th emission control line EMLj among the emission control lines EML1 to EMLn.

The pixel PXij may include a light emitting element ED and a pixel drive circuit PDC. The light emitting element ED may be a light emitting diode. In an embodiment, the light emitting element ED may be an organic light emitting diode including an organic light emitting layer, but embodiments are not limited thereto.

The pixel drive circuit PDC may include first to fifth transistors T1, T2, T3, T4, and T5, first and second emission control transistors ET1 and ET2, and a capacitor Cst.

At least one of the first to fifth transistors T1, T2, T3, T4, and T5 and the first and second emission control transistors ET1 and ET2 may be a transistor having a low-temperature polycrystalline silicon (LTPS) semiconductor layer. At least one of the first to fifth transistors T1, T2, T3, T4, and T5 and the first and second emission control transistors ET1 and ET2 may be a transistor having an oxide semiconductor layer. For example, the third and fourth transistors T3 and T4 may be oxide semiconductor transistors, and the first, second, and fifth transistors T1, T2, and T5 and the first and second emission control transistors ET1 and ET2 may be low-temperature polycrystalline silicon (LTPS) transistors.

For example, the first transistor T1 directly affecting the brightness of the display device 1000 (refer to FIG. 1) may include a semiconductor layer formed of polycrystalline silicon having high reliability, and thus the display device having a high resolution may be implemented. For example, an oxide semiconductor may have high carrier mobility and low leakage current, and therefore a voltage drop may not be great even though operating time is long. For example, the color of an image may not be greatly changed according to a voltage drop even during a low-frequency operation, and thus the low-frequency operation may be possible. As the oxide semiconductor has an advantage of low leakage current as described above, at least one of the third transistor T3, which is connected to a third electrode (or a gate electrode) of the first transistor T1, and the fourth transistor T4 may be formed as an oxide semiconductor to reduce power consumption while preventing leakage current that is likely to flow to the gate electrode.

Some of the first to fifth transistors T1, T2, T3, T4, and T5 and the first and second emission control transistors ET1 and ET2 may be P-type transistors, and the others may be N-type transistors. For example, the first, second, and fifth transistors T1, T2, and T5 and the first and second emission control transistors ET1 and ET2 may be P-type transistors, and the third and fourth transistors T3 and T4 may be N-type transistors.

The configuration of the pixel drive circuit PDC according to an embodiment is not limited to the embodiment illustrated in FIG. 4. The pixel drive circuit PDC illustrated in FIG. 4 is an example, and various changes and modifications may be made to the configuration of the pixel drive circuit PDC. For example, the first to fifth transistors T1, T2, T3, T4, and T5 and the first and second emission control transistors ET1 and ET2 may all be P-type transistors or N-type transistors.

The j-th initialization scan line SILj, the j-th compensation scan line SCLj, the j-th write scan line SWLj, the j-th black scan line SBLj, and the j-th emission control line EMLj may transfer the j-th initialization scan signal SIj, the j-th compensation scan signal SCj, the j-th write scan signal SWj, the j-th black scan signal SBj, and the j-th emission control signal EMj to the pixel PXij, respectively. The i-th data line DLi may transfer the i-th data signal Di to the pixel PXij. The i-th data signal Di may have a voltage level corresponding to the image data RGB (refer to FIG. 2) that is input to the display device 1000 (refer to FIG. 2).

First and second drive voltage lines VL1 and VL2 may transfer the first drive voltage ELVDD and the second drive voltage ELVSS to the pixel PXij, respectively. For example, first and second initialization voltage lines VL3 and VL4 may transfer the first initialization voltage VINT1 and the second initialization voltage VINT2 to the pixel PXij, respectively.

The first transistor T1 may be connected between the first drive voltage line VL1, which receives the first drive voltage ELVDD, and the light emitting element ED. The first transistor T1 may include a first electrode connected to the first drive voltage line VL1 via the first emission control transistor ET1, a second electrode connected to the light emitting element ED via the second emission control transistor ET2, and the third electrode (e.g., the gate electrode) connected to an end portion of the capacitor Cst (e.g., a first node N1). The first transistor T1 may receive the i-th data signal Di, which is transferred through the i-th data line DLi according to a switching operation of the second transistor T2, and may supply a drive current Id to the light emitting element ED.

The second transistor T2 may be connected between the i-th data line DLi and the first electrode of the first transistor T1. The second transistor T2 may include a first electrode connected to the i-th data line DLi, a second electrode connected to the first electrode of the first transistor T1, and a third electrode (e.g., a gate electrode) connected to the j-th write scan line SWLj. The second transistor T2 may be turned on based on the j-th write scan signal SWj transferred through the j-th write scan line SWLj, and may transfer, to the first electrode of the first transistor T1, the i-th data signal Di transferred from the i-th data line DLi.

The third transistor T3 may be connected between the second electrode of the first transistor T1 and the first node N1. The third transistor T3 may include a first electrode connected to the third electrode of the first transistor T1, a second electrode connected to the second electrode of the first transistor T1, and a third electrode (e.g., a gate electrode) connected to the j-th compensation scan line SCLj. The third transistor T3 may be turned on based on the j-th compensation scan signal SCj transferred through the j-th compensation scan line SCLj, and may diode-connect the first transistor T1 by connecting the third electrode and the second electrode of the first transistor T1.

The fourth transistor T4 may be connected between the first initialization voltage line VL3, through which the first initialization voltage VINT1 is applied, and the first node N1. The fourth transistor T4 may include a first electrode connected to the first initialization voltage line VL3 through which the first initialization voltage VINT1 is transferred, a second electrode connected to the first node N1, and a third electrode (e.g., a gate electrode) connected to the j-th initialization scan line SILj. The fourth transistor T4 may be turned on based on the j-th initialization scan signal SIj transferred through the j-th initialization scan line SILj. The turned-on fourth transistor T4 may initialize the potential of the third electrode of the first transistor T1 (e.g., the potential of the first node N1) by transferring the first initialization voltage VINT1 to the first node N1.

The first emission control transistor ET1 may include a first electrode connected to the first drive voltage line VL1, a second electrode connected to the first electrode of the first transistor T1, and a third electrode (e.g., a gate electrode) connected to the j-th emission control line EMLj.

The second emission control transistor ET2 may include a first electrode connected to the second electrode of the first transistor T1, a second electrode connected to the light emitting element ED, and a third electrode (e.g., a gate electrode) connected to the j-th emission control line EMLj.

The first and second emission control transistors ET1 and ET2 may be simultaneously turned on based on the j-th emission control signal EMj transferred through the j-th emission control line EMLj. The first drive voltage ELVDD may be applied to the diode-connected first transistor T1 through the turned-on first emission control transistor ET1, and may be compensated (or adjusted) by passing through the diode-connected first transistor T1, and the compensated (or adjusted) voltage may be transferred to the light emitting element ED.

The fifth transistor T5 may include a first electrode connected to the second initialization voltage line VL4 through which the second initialization voltage VINT2 is transferred, a second electrode connected to the second electrode of the second emission control transistor ET2 (e.g., a second node N2), and a third electrode (e.g., a gate electrode) connected to the j-th black scan line SBLj. The second initialization voltage VINT2 may have a voltage level lower than or equal to the voltage level of the first initialization voltage VINT1.

The end portion of the capacitor Cst may be connected to the third electrode of the first transistor T1 as described above, and an opposite end portion of the capacitor Cst may be connected to the first drive voltage line VL1. A cathode of the light emitting element ED may be connected to the second drive voltage line VL2 that transfers the second drive voltage ELVSS. The second drive voltage ELVSS may have a lower voltage level than the first drive voltage ELVDD.

The sensor FXdj may be connected to the d-th readout line RLd among the readout lines RL1 to RLh, the j-th write scan line SWLj (referred to as the output control line), and a reset control line RCL.

The sensor FXdj may include a light sensing element OPD (referred to as a sensing element) and a sensor drive circuit O_SD.

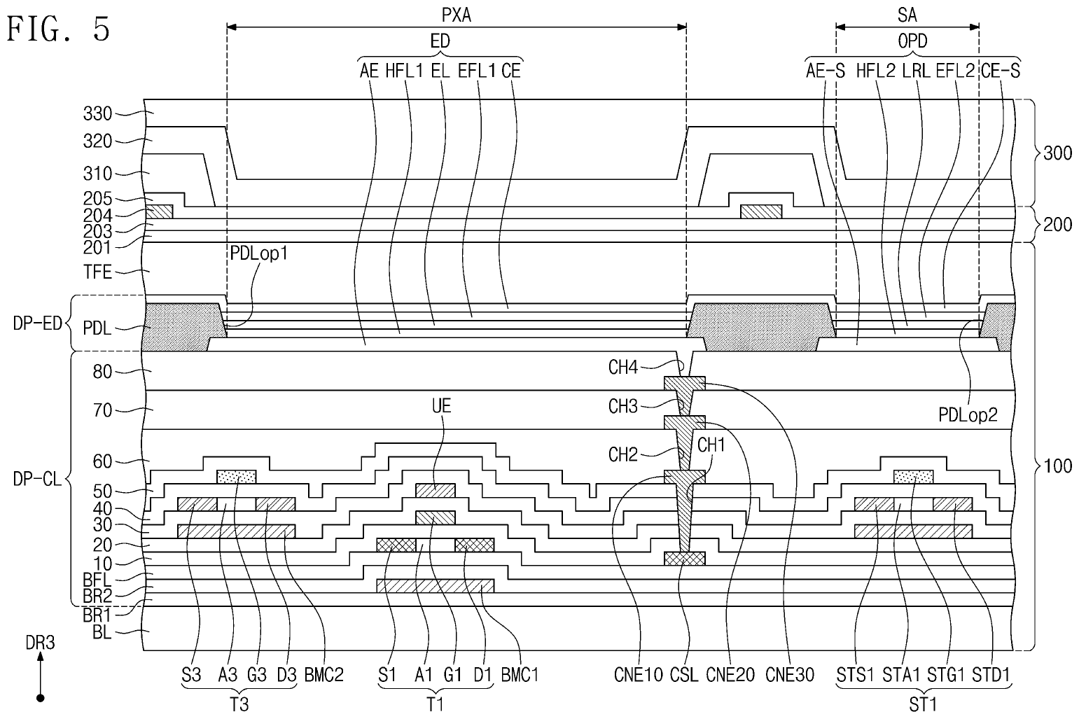

The light sensing element OPD may be a photo diode. In an embodiment, the light sensing element OPD may be an organic photo diode including an organic material as a photoelectric conversion layer. A first electrode AE-S(refer to FIG. 5) of the light sensing element OPD may be connected to a first sensing node SN1, and a second electrode CE-S (refer to FIG. 5) of the light sensing element OPD may be connected to the second drive voltage line VL2 that transfers the second drive voltage ELVSS. Although FIG. 4 illustrates an example that the sensor FXdj may include a light sensing element (e.g., single light sensing element) OPD, embodiments are not limited thereto. For example, the sensor FXdj may include z light sensing elements connected in parallel. “z” may be an integer of 2 or larger.

The sensor drive circuit O_SD may include three transistors ST1, ST2, and ST3. The three transistors ST1, ST2, and ST3 may include the reset transistor ST1, the amplifying transistor ST2, and the output transistor ST3. At least one of the reset transistor ST1, the amplifying transistor ST2, and the output transistor ST3 may be an oxide semiconductor transistor. In an embodiment, the reset transistor ST1 may be an oxide semiconductor transistor, and the amplifying transistor ST2 and the output transistor ST3 may be low-temperature polycrystalline silicon (LTPS) transistors. However, embodiments are not limited thereto, at least the reset transistor ST1 and the output transistor ST3 may be oxide semiconductor transistors, and the amplifying transistor ST2 may be a low-temperature polycrystalline silicon (LTPS) transistor.

Furthermore, some of the reset transistor ST1, the amplifying transistor ST2, and the output transistor ST3 may be P-type transistors, and the rest may be an N-type transistor. In an embodiment, the amplifying transistor ST2 and the output transistor ST3 may be P-type transistors, and the reset transistor ST1 may be an N-type transistor. However, embodiments are not limited thereto, the reset transistor ST1, the amplifying transistor ST2, and the output transistor ST3 may all be N-type transistors or P-type transistors.

A circuit configuration of the sensor drive circuit O_SD according to an embodiment is not limited to that illustrated in FIG. 4. The sensor drive circuit O_SD illustrated in FIG. 4 is an example, and various changes and modifications may be made to the configuration of the sensor drive circuit O_SD.

The reset transistor ST1 may include a first electrode, which is connected to a third initialization voltage line VL5 and receives the reset voltage Vrst, a second electrode connected to the first sensing node SN1, and a third electrode which receives a reset control signal RST. The reset transistor ST1 may reset the potential of the first sensing node SN1 to the reset voltage Vrst in response to the reset control signal RST. The reset control signal RST may be a signal provided through the reset control line RCL.

The amplifying transistor ST2 may include a first electrode, which receives a sensing drive voltage SLVD, a second electrode connected to a second sensing node SN2, and a third electrode connected to the first sensing node SN1. The amplifying transistor ST2 may be turned on based on the potential of the first sensing node SN1, and may apply the sensing drive voltage SLVD to the second sensing node SN2. In an embodiment, the sensing drive voltage SLVD may be one of the first drive voltage ELVDD and the first and second initialization voltages VINT1 and VINT2. In case that the sensing drive voltage SLVD is the first drive voltage ELVDD, the first electrode of the amplifying transistor ST2 may be electrically connected to the first drive voltage line VL1. In case that the sensing drive voltage SLVD is the first initialization voltage VINT1, the first electrode of the amplifying transistor ST2 may be electrically connected to the first initialization voltage line VL3, and in case that the sensing drive voltage SLVD is the second initialization voltage VINT2, the first electrode of the amplifying transistor ST2 may be electrically connected to the second initialization voltage line VL4.

The output transistor ST3 may include a first electrode connected to the second sensing node SN2, a second electrode connected to the d-th readout line RLd, and a third electrode which receives an output control signal. In response to the output control signal, the output transistor ST3 may transfer a detection signal FSd to the d-th readout line RLd. The output control signal may be the j-th write scan signal SWj (referred to as the j-th output control signal) supplied through the j-th write scan line SWLj. For example, the output transistor ST3 may receive the j-th write scan signal SWj, which is supplied from the j-th write scan line SWLj, as the output control signal.

A reset period may be defined as an activation period (e.g., a high-level period) of the reset control line RCL. In case that the reset control signal RST having a high level is supplied through the reset control line RCL, the reset transistor ST1 may be turned on. In another example, in case that the reset transistor ST1 is implemented as a PMOS transistor, the reset control signal RST having a low level may be supplied to the reset control line RCL during the reset period. The first sensing node SN1 may be reset to a potential corresponding to the reset voltage Vrst during the reset period. In an embodiment, the reset voltage Vrst may have a lower voltage level than the second drive voltage ELVSS.

The light sensing element OPD of the sensor FXdj may be exposed to light during a light emission period of the light emitting element ED. The voltage of the first sensing node SN1 may remain at the reset voltage Vrst in the reset period, and as the light sensing element OPD is exposed to light, the voltage of the first sensing node SN1 may be gradually shifted to the second drive voltage ELVSS. The amplifying transistor ST2 may be a source follower amplifier that generates a source-drain current in proportion to the amount of charge of the first sensing node SN1 that is input to the third electrode.

The j-th write scan signal SWj having a low level may be supplied to the output transistor ST3 through the j-th write scan line SWLj in an output period. In case that the output transistor ST3 is turned on in response to the j-th write scan signal SWj having the low level, the detection signal FSd corresponding to a current flowing through the amplifying transistor ST2 may be output to the d-th readout line RLd.

FIG. 5 is a schematic sectional view of the display panel according to an embodiment.

Referring to FIG. 5, the display panel DP may include the display layer 100, the sensor layer 200, and an anti-reflective layer 300.

The display layer 100 may include a base layer BL, and a circuit layer DP-CL, an element layer DP-ED, and an encapsulation layer TFE sequentially disposed on the base layer BL.

At least one inorganic layer may be formed on an upper surface of the base layer BL. The inorganic layer may include at least one of aluminum oxide, titanium oxide, silicon oxide, silicon oxynitride, zirconium oxide, and hafnium oxide. The inorganic layer may be formed as multiple layers. The multiple inorganic layers may constitute barrier layers BR1 and BR2 and/or a buffer layer BFL that will be described below. The barrier layers BR1 and BR2 and the buffer layer BFL may be selectively disposed.

The barrier layers BR1 and BR2 may prevent infiltration (or permeation) of foreign matter from the outside. The barrier layers BR1 and BR2 may include a silicon oxide layer and a silicon nitride layer. Silicon oxide layers and silicon nitride layers may be provided. The silicon oxide layers and the silicon nitride layers may be alternately stacked with each other.

The barrier layers BR1 and BR2 may include the first barrier layer BR1 and the second barrier layer BR2. A first back metal layer BMC1 may be disposed between the first barrier layer BR1 and the second barrier layer BR2. In another example, the first back metal layer BMC1 may be omitted.

The buffer layer BFL may be disposed on the barrier layers BR1 and BR2. The buffer layer BFL may improve a coupling force between the base layer BL and a semiconductor pattern and/or a conductive pattern. The buffer layer BFL may include silicon oxide layers and silicon nitride layers. The silicon oxide layers and the silicon nitride layers may be alternately stacked with each other.

A first semiconductor pattern may be disposed on the buffer layer BFL. The first semiconductor pattern may include a silicon semiconductor. For example, the silicon semiconductor may include amorphous silicon or polycrystalline silicon. For example, the first semiconductor pattern may include low-temperature polycrystalline silicon.

FIG. 5 illustrates only a portion of the first semiconductor pattern disposed on the buffer layer BFL, and another portion of the first semiconductor pattern may be additionally disposed in other regions. The first semiconductor pattern may be arranged across the pixels according to a specific rule (or specific pattern). The first semiconductor pattern may have different electrical properties according to whether the first semiconductor pattern is doped or not. The first semiconductor pattern may include a first region having a high conductivity and a second region having a low conductivity. The first region may be doped with an N-type dopant or a P-type dopant. A P-type transistor may include a doped region that is doped with a P-type dopant, and an N-type transistor may include a doped region that is doped with an N-type dopant. The second region may be an un-doped region, or may be a region more lightly doped than the first region.

The conductivity of the first region may be higher than the conductivity of the second region, and the first region may substantially function as an electrode or a signal line. The second region may substantially correspond to an active region (or a channel) of a transistor. For example, a portion of the first semiconductor pattern may be the active region of the transistor, another portion may be a source or drain of the transistor, and the other portion may be a connecting electrode or a connecting signal line.

The first electrode S1, an active region A1, and the second electrode DI of the first transistor T1 may be formed from the first semiconductor pattern. The first electrode S1 and the second electrode DI of the first transistor T1 may extend from the active region A1 in opposite directions.

In FIG. 5, a portion of a connecting signal line CSL formed from the first semiconductor pattern is illustrated. For example, the connecting signal line CSL may be connected to the second electrode of the fifth transistor T5 (refer to FIG. 4) and the second emission control transistor ET2 in plan view.

A first insulating layer 10 may be disposed on the buffer layer BFL. The first insulating layer 10 may commonly overlap the pixels, and may cover the first semiconductor pattern. The first insulating layer 10 may be an inorganic layer and/or an organic layer, and may have a single-layer structure or a multi-layer structure. The first insulating layer 10 may include at least one of aluminum oxide, titanium oxide, silicon oxide, silicon nitride, silicon oxynitride, zirconium oxide, and hafnium oxide. In an embodiment, the first insulating layer 10 may be a single silicon oxide layer. Not only the first insulating layer 10 but also insulating layers of the circuit layer DP-CL that will be described below may be inorganic layers and/or organic layers, and may have a single-layer structure or a multi-layer structure. The inorganic layers may include at least one of the aforementioned materials, but embodiments are not limited thereto.

The third electrode G1 of the first transistor T1 may be disposed on the first insulating layer 10. The third electrode G1 may be a portion of a metal pattern. The third electrode G1 of the first transistor T1 may overlap the active region A1 of the first transistor T1. The third electrode G1 of the first transistor T1 may function as a mask in a process of doping the first semiconductor pattern. The third electrode G1 may include titanium (Ti), silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), indium tin oxide (ITO), or indium zinc oxide (IZO), but embodiments are not limited thereto.

A second insulating layer 20 may be disposed on the first insulating layer 10, and may cover the third electrode G1 of the first transistor T1. The second insulating layer 20 may be an inorganic layer and/or an organic layer, and may have a single-layer structure or a multi-layer structure. The second insulating layer 20 may include at least one of silicon oxide, silicon nitride, and silicon oxynitride. In an embodiment, the second insulating layer 20 may have a multi-layer structure including a silicon oxide layer and a silicon nitride layer.

An upper electrode UE and a second back metal layer BMC2 may be disposed on the second insulating layer 20. The upper electrode UE may overlap the third electrode G1. The upper electrode UE may be a portion of a metal pattern. A portion of the third electrode G1 and the upper electrode UE overlapping the portion of the third electrode G1 may form the capacitor Cst (refer to FIG. 4). In an embodiment, the second insulating layer 20 may be replaced with an insulating pattern. For example, the upper electrode UE may be disposed on the insulating pattern. The upper electrode UE may function as a mask that forms the insulating pattern from the second insulating layer 20.

The second back metal layer BMC2 may be disposed under an oxide thin film transistor, for example, the third transistor T3, to overlap the third transistor T3. A constant voltage or a signal may be applied to the second back metal layer BMC2.

A third insulating layer 30 may be disposed on the second insulating layer 20, and may cover the upper electrode UE and the second back metal layer BMC2. The third insulating layer 30 may have a single-layer structure or a multi-layer structure. For example, the third insulating layer 30 may have a multi-layer structure including a silicon oxide layer and a silicon nitride layer.

A second semiconductor pattern may be disposed on the third insulating layer 30. The second semiconductor pattern may include an oxide semiconductor. The oxide semiconductor may include a plurality of regions, which are distinguished according to whether metal oxide is reduced (or deoxidized) or not. A region where metal oxide is reduced (hereinafter, referred to as the reduced region) may have a higher conductivity than a region where metal oxide is not reduced (hereinafter, referred to as the non-reduced region). The reduced region may substantially function as a source/drain of a transistor or a signal line. The non-reduced region may substantially function as an active region (or a semiconductor region or a channel) of the transistor. For example, a portion of the second semiconductor pattern may be the active region of the transistor, another portion may be the source/drain region of the transistor, and the other portion may be a signal transmission region.

The first electrode S3, an active region A3, and the second electrode D3 of the third transistor T3 may be formed from the second semiconductor pattern. The first electrode S3 and the second electrode D3 may include a metal, which is reduced (or deoxidized) from a metal oxide semiconductor. The first electrode S3 and the second electrode D3 may extend from the active region A3 in opposite directions on the section.

A fourth insulating layer 40 may be disposed on the third insulating layer 30. The fourth insulating layer 40 may commonly overlap the pixels, and may cover the second semiconductor pattern. The fourth insulating layer 40 may include at least one of aluminum oxide, titanium oxide, silicon oxide, silicon nitride, silicon oxynitride, zirconium oxide, and hafnium oxide.

The third electrode G3 of the third transistor T3 may be disposed on the fourth insulating layer 40. The third electrode G3 may be a portion of a metal pattern. The third electrode G3 of the third transistor T3 may overlap the active region A3 of the third transistor T3. The third electrode G3 may function as a mask in a process of reducing the second semiconductor pattern. In an embodiment, the fourth insulating layer 40 may be replaced with an insulating pattern.

A fifth insulating layer 50 may be disposed on the fourth insulating layer 40, and may cover the third electrode G3. The fifth insulating layer 50 may be an inorganic layer.

A first connecting electrode CNE10 may be disposed on the fifth insulating layer 50. The first connecting electrode CNE10 may be connected to the connecting signal line CSL through a first contact hole CH1 penetrating (or passing through) the first to fifth insulating layers 10, 20, 30, 40, and 50.

A sixth insulating layer 60 may be disposed on the fifth insulating layer 50. The sixth insulating layer 60 may be an organic layer. The organic layer may include, but embodiments are not limited to, a general purpose polymer, such as benzocyclobutene (BCB), polyimide, hexamethyldisiloxane (HMDSO), Polymethylmethacrylate (PMMA), or Polystyrene (PS), a polymer derivative having a phenolic group, an acrylic polymer, an imide-based polymer, an aryl ether-based polymer, an amide-based polymer, a fluorine-based polymer, a p-xylene-based polymer, a vynyl alcohol-based polymer, or a blend thereof.

A second connecting electrode CNE20 may be disposed on the sixth insulating layer 60. The second connecting electrode CNE20 may be connected to the first connecting electrode CNE10 through a second contact hole CH2 penetrating (or passing through) the sixth insulating layer 60. A seventh insulating layer 70 may be disposed on the sixth insulating layer 60, and may cover the second connecting electrode CNE20. The seventh insulating layer 70 may be an organic layer.

A third connecting electrode CNE30 may be disposed on the seventh insulating layer 70. The third connecting electrode CNE30 may be connected to the second connecting electrode CNE20 through a third contact hole CH3 penetrating (or passing through) the seventh insulating layer 70. An eighth insulating layer 80 may be disposed on the seventh insulating layer 70, and may cover the third connecting electrode CNE30. The eighth insulating layer 80 may be an organic layer.

The circuit layer DP-CL may further include the sensor drive circuit O_SD (refer to FIG. 4). For convenience of description, the reset transistor ST1 of the sensor drive circuit O_SD is illustrated. The first electrode STS1, an active region STA1, and the second electrode STD1 of the reset transistor ST1 may be formed from the second semiconductor pattern. The first electrode STS1 and the second electrode STD1 may include a metal which is reduced (or deoxidized) from a metal oxide semiconductor. The fourth insulating layer 40 may cover the first electrode STS1, the active region STA1, and the second electrode STD1 of the reset transistor ST1. The third electrode STG1 of the reset transistor ST1 may be disposed on the fourth insulating layer 40. In an embodiment, the third electrode STG1 may be a portion of a metal pattern. The third electrode STG1 of the reset transistor ST1 may overlap the active region STA1 of the reset transistor T1.

In an embodiment, the reset transistor ST1 and the third transistor T3 may be disposed on the same layer (e.g., third insulating layer 30). For example, the first electrode STS1, the active region STA1, and the second electrode STD1 of the reset transistor ST1 and the first electrode S3, the active region A3, and the second electrode D3 of the third transistor T3 may be formed by the same process. The third electrode STG1 of the reset transistor ST1 may be simultaneously formed together with the third electrode G3 of the third transistor T3 by the same process. For example, the first electrodes and the second electrodes of the amplifying transistor ST2 and the output transistor ST3 of the sensor drive circuit O_SD may be formed by the same process as the first electrode S1 and the second electrode DI of the first transistor T1. The reset transistor ST1 and the third transistor T3 may be formed on the same layer by the same process, and thus an additional process for forming the reset transistor ST1 is not required. Accordingly, process efficiency may be improved, and the manufacturing cost may be reduced.

The element layer DP-ED may be disposed on the circuit layer DP-CL. The element layer DP-ED may include light emitting elements ED and light sensing elements OPD. In FIG. 5, a light emitting element (e.g., single light emitting element) ED and a light sensing element (e.g., single light sensing element) OPD are representatively illustrated.

A light emitting region PXA may be defined to correspond to the light emitting element ED, and a sensing region SA may be defined to correspond to the light sensing element OPD. The light emitting region PXA and the sensing region SA may be defined by a pixel defining layer PDL that will be described below.

The light emitting element ED may include a first electrode AE, a first hole control layer HFL1, a light emitting layer EL, a first electron control layer EFL1, and a second electrode CE. The light sensing element OPD may include the first electrode AE-S, a second hole control layer HFL2, a photoelectric conversion layer LRL, a second electron control layer EFL2, and the second electrode CE-S. For example, the first electrode AE of the light emitting element ED may be referred to as the first light emitting electrode, and the second electrode CE of the light emitting element ED may be referred to as the second light emitting electrode. The first electrode AE-S of the light sensing element OPD may be referred to as the first light sensing electrode, and the second electrode CE-S of the light sensing element OPD may be referred to as the second light sensing electrode.

The second electrodes CE and CE-S may be commonly provided for the pixels PX (refer to FIG. 3) and the sensors FX (refer to FIG. 3). For example, the second electrode CE of the light emitting element ED and the second electrode CE-S of the light sensing element OPD may be connected to be integral with each other. The second electrodes CE and CE-S may be connected to each other on the pixel defining layer PDL.

Referring to FIG. 5, the first electrode AE of the light emitting element ED and the first electrode AE-S of the light sensing element OPD may be disposed on the eighth insulating layer 80. The first electrode AE of the light emitting element ED may be connected to the third connecting electrode CNE30 through a fourth contact hole CH4 penetrating (or passing through) the eighth insulating layer 80.

For example, each of the light emitting element ED and the light sensing element OPD may further include an auxiliary layer. The auxiliary layer may be disposed between the first hole control layer HFL1 and the light emitting layer EL and between the second hole control layer HFL2 and the photoelectric conversion layer LRL.

The pixel defining layer PDL may be disposed on the eighth insulating layer 80, and may cover portions of the first electrodes AE and AE-S. Openings PDLop1 and PDLop2 may be provided in the pixel defining layer PDL. Light emitting regions PXA and sensing regions SA may be defined by the openings PDLop1 and PDLop2.

The light emitting region PXA may be defined by the first opening PDLop1, and the sensing region SA may be defined by the second opening PDLop2. The first opening PDLop1 may expose at least a portion of the first electrode AE of the light emitting element ED, and the second opening PDLop2 may expose at least a portion of the first electrode AE-S of the light sensing element OPD.

In an embodiment, the pixel defining layer PDL may further include a black material. The pixel defining layer PDL may further include a black organic dye/pigment, such as carbon black, aniline black, or the like. The pixel defining layer PDL may be formed by mixing a blue organic material and a black organic material. The pixel defining layer PDL may further include a liquid-repellent organic material. The pixel defining layer PDL may include a portion including a liquid-repellent organic material. Detailed description thereabout will be given below.

The light emitting layer EL of the light emitting element ED may be disposed in a region corresponding to the first opening PDLop1. The light emitting layer EL may generate certain colored light. Although the patterned light emitting layer EL has been described as an example in an embodiment, a light emitting layer (e.g., single light emitting layer) may be commonly disposed in the light emitting regions. For example, the light emitting layer may generate white light or blue light. For example, the light emitting layer may have a multi-layer structure called a tandem.

The light emitting layer EL may include a low molecular weight organic material or a high molecular weight organic material as a luminescent material. In another example, the light emitting layer EL may include a quantum dot material as a luminescent material. A core of a quantum dot may be selected from Group II-VI compounds, Group III-V compounds, Group III-VI compounds, Group I-III-VI compounds, Group IV-VI compounds, Group IV elements, Group IV compounds, and combinations thereof.

The photoelectric conversion layer LRL may be disposed in a region corresponding to the second opening PDLop2. The photoelectric conversion layer LRL may include an organic photo sensing material. The second electrode CE-S may be disposed on the photoelectric conversion layer LRL. The first electrode AE-S and the second electrode CE-S may each receive an electrical signal. The first electrode AE-S and the second electrode CE-S may receive different signals. Accordingly, an electric field may be formed between the first electrode AE-S and the second electrode CE-S. The photoelectric conversion layer LRL may generate an electrical signal corresponding to light incident to the sensor.

Charges generated in the photoelectric conversion layer LRL may change the electric field between the first electrode AE-S and the second electrode CE-S. The amount of charges generated in the photoelectric conversion layer LRL may vary according to whether light is incident to the light sensing element OPD and the amount and intensity of light incident to the light sensing element OPD. Accordingly, the electric field formed between the first electrode AE-S and the second electrode CE-S may vary. The light sensing element OPD according to an embodiment may obtain fingerprint information of the user through the change in the electric field between the first electrode AE-S and the second electrode CE-S.

For example, the element layer DP-ED may further include a capping layer disposed on the second electrodes CE and CE-S. The capping layer may function to improve light emission efficiency by the principle of constructive interference. The capping layer may include, for example, a material having a refractive index of about 1.6 or more for light having a wavelength of about 589 nm. The capping layer may be an organic capping layer including an organic material, an inorganic capping layer including an inorganic material, or a composite capping layer including an organic material and an inorganic material. For example, the capping layer may include a carbocyclic compound, a heterocyclic compound, an amine group-containing compound, a porphine derivative, a phthalocyanine derivative, a naphthalocyanine derivative, an alkali metal complex, an alkaline earth metal complex, or a combination thereof. A substituent including O, N, S, Se, Si, F, Cl, Br, I, or a combination thereof may be selectively substituted for the carbocyclic compound, the heterocyclic compound, and the amine group-containing compound.

The encapsulation layer TFE may be disposed on the element layer DP-ED. The encapsulation layer TFE may include at least an inorganic layer or an organic layer. In an embodiment, the encapsulation layer TFE may include two inorganic layers and an organic layer disposed therebetween. In an embodiment, the encapsulation layer may include inorganic layers and organic layers that are alternately stacked with each other.

The inorganic encapsulation layers may protect the light emitting element ED and the light sensing element OPD from moisture/oxygen, and the organic encapsulation layers may protect the light emitting element ED and the light sensing element OPD from foreign matter such as dust particles. The inorganic encapsulation layers may include a silicon nitride layer, a silicon oxynitride layer, a silicon oxide layer, a titanium oxide layer, or an aluminum oxide layer, but embodiments are not limited thereto. The organic encapsulation layers may include an acrylic organic layer, but embodiments are not limited thereto.

The sensor layer 200 may be disposed on the display layer 100. The sensor layer 200 may sense an external input applied from the outside. The external input may be an input of the user. The input of the user may include various types of external inputs, such as a part of the user's body, light, heat, a pen, or pressure. The sensor layer 200 may be referred to as a sensor, an input sensing layer, or an input sensing panel. The sensor layer 200 may include a sensor base layer 201, a first sensor conductive layer, a sensor insulating layer 203, a second sensor conductive layer 204, and a sensor cover layer 205.

The sensor base layer 201 may be disposed (e.g., directly disposed) on the display layer 100. The sensor base layer 201 may be an inorganic layer including at least one of silicon nitride, silicon oxynitride, and silicon oxide. In another example, the sensor base layer 201 may be an organic layer including an epoxy resin, an acrylic resin, or an imide-based resin. The sensor base layer 201 may have a single-layer structure, or may have a multi-layer structure stacked in the third direction DR3.

Each of the first sensor conductive layer and the second sensor conductive layer 204 may have a single-layer structure, or may have a multi-layer structure stacked in the third direction DR3.

The conductive layer having a single-layer structure may include a metal layer or a transparent conductive layer. The metal layer may include molybdenum, silver, titanium, copper, aluminum, or an alloy thereof. The transparent conductive layer may include transparent conductive oxide such as indium tin oxide, indium zinc oxide, zinc oxide, or indium zinc tin oxide. For example, the transparent conductive layer may include a conductive polymer such as poly(3,4-ethylenedioxythiophene) (PEDOT), a metal nano-wire, or graphene.

The conductive layer having a multi-layer structure may include metal layers. The meal layers may have, for example, a three-layer structure of titanium/aluminum/titanium. The conductive layer having a multi-layer structure may include at least one metal layer and at least one transparent conductive layer.

The sensor insulating layer 203 may be disposed between the first sensor conductive layer and the second sensor conductive layer 204. The sensor insulating layer 203 may include an inorganic film. The inorganic film may include at least one of aluminum oxide, titanium oxide, silicon oxide, silicon nitride, silicon oxynitride, zirconium oxide, and hafnium oxide.

In another example, the sensor insulating layer 203 may include an organic film. The organic film may include at least one of an acrylic resin, a methacrylic resin, a polyisoprene resin, a vinyl resin, an epoxy resin, a urethane-based resin, a celluosic resin, a siloxane-based resin, a polyimide resin, a polyamide resin, and a perylene-based resin.

The sensor cover layer 205 may be disposed on the sensor insulating layer 203, and may cover the second sensor conductive layer 204. The second sensor conductive layer 204 may include a conductive pattern. The sensor cover layer 205 may cover the conductive pattern, and may reduce or eliminate a probability of damage to the conductive pattern in a subsequent process. The sensor cover layer 205 may include an inorganic material. For example, the sensor cover layer 205 may include silicon nitride, but embodiments are not limited thereto. In another example, the sensor cover layer 205 may be omitted.

The anti-reflective layer 300 may be disposed on the sensor layer 200. The anti-reflective layer 300 may include a dividing layer 310, color filters 320, and a planarization layer 330.

The dividing layer 310 may overlap the conductive pattern of the second sensor conductive layer 204. The sensor cover layer 205 may be disposed between the dividing layer 310 and the second sensor conductive layer 204. The dividing layer 310 may prevent reflection of external light by the second sensor conductive layer 204. A material constituting the dividing layer 310 is not limited as long as it is a material capable of absorbing light. The dividing layer 310 may be a black layer. In an embodiment, the dividing layer 310 may include a black coloring agent. The black coloring agent may include a black dye or a black pigment. The black coloring agent may include carbon black, metal such as chromium, or oxide thereof.

The dividing layer 310 may have dividing openings defined (or formed) therein. The dividing openings may overlap the light emitting layer EL and the photoelectric conversion layer LRL, respectively. The color filters 320 may be disposed to correspond to the dividing openings. The color filters 320 may transmit light provided from the light emitting layers EL overlapping the color filters 320. In another example, light may be transmitted through the color filters 320, and may be provided to the photoelectric conversion layer LRL.

The light emitting layer EL may be a green light emitting layer. Accordingly, a color filter (e.g., single color filter) 320 may be commonly provided for the light emitting layer EL and the photoelectric conversion layer LRL. However, embodiments are not limited thereto. For example, another color filter rather than a green color filter may be disposed over the photoelectric conversion layer LRL. In another example, the color filter 320 may not be disposed over the photoelectric conversion layer LRL.

The planarization layer 330 may cover the dividing layer 310 and the color filters 320. The planarization layer 330 may include an organic material, and may provide a flat surface on an upper surface of the planarization layer 330. In another example, the planarization layer 330 may be omitted.

In an embodiment, the anti-reflective layer 300 may include a reflection control layer instead of the color filters 320. For example, the color filters 320 may be omitted in FIG. 5, and the reflection control layer may be added at the places where the color filters 320 are omitted. The reflection control layer may selectively absorb light having a partial band of light reflected inside the display panel and/or the display device or light having a partial band of light incident from outside the display panel and/or the display device.

For example, the reflection control layer may absorb light having a first wavelength range of about 490 nm to about 505 nm and light having a second wavelength range of about 585 nm to about 600 nm, and thus the light transmittance in the first wavelength range and the second wavelength range may be about 40% or less. The reflection control layer may absorb light outside the wavelength ranges of red light, green light, and blue light emitted from the light emitting layers EL. As the reflection control layer absorbs light outside the wavelength range of the red light, the green light, or the blue light emitted from the light emitting layer EL as described above, a decrease in the luminance of the display panel and/or the display device may be prevented or minimized. For example, deterioration in the light emission efficiency of the display panel and/or the display device may be prevented or minimized, and visibility may be improved.

The reflection control layer may be implemented as an organic layer including a dye, a pigment, or a combination thereof. The reflection control layer may include a tetraazaporphyrin (TAP)-based compound, a porphyrin-based compound, a metal porphyrin-based compound, an oxazine-based compound, a squarylium-based compound, a triarylmethane-based compound, a polymethine-based compound, an anthraquinone-based compound, a phthalocyanine-based compound, an azo-based compound, a perylene-based compound, a xanthene-based compound, a diimmonium-based compound, a dipyrromethene-based compound, a cyanine-based compound, and a combination thereof.

In an embodiment, the reflection control layer may have a transmittance of about 64% to about 72%. The transmittance of the reflection control layer may be adjusted according to the content of the pigment and/or dye included in the reflection control layer.

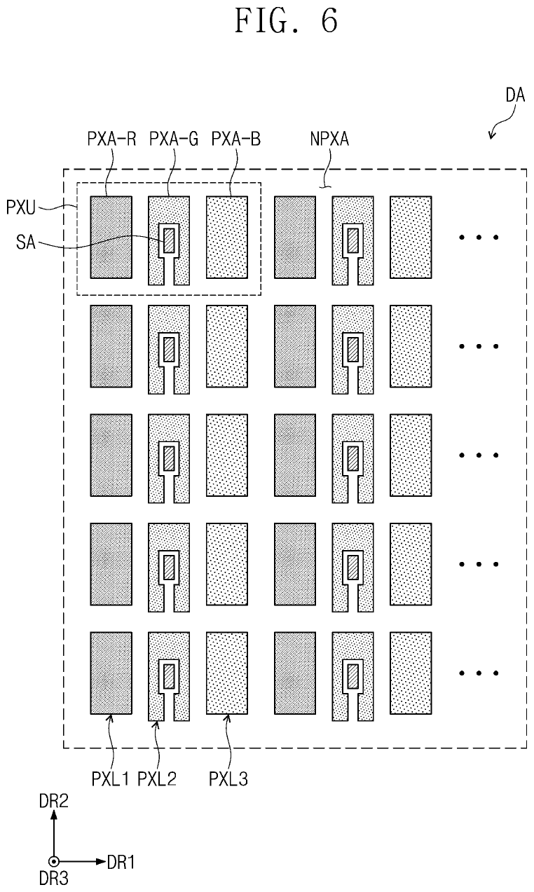

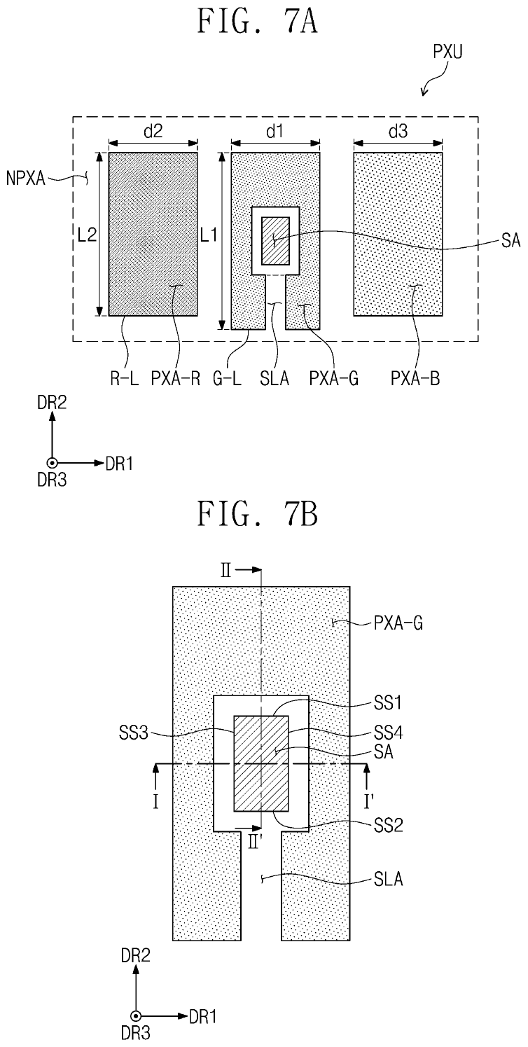

FIG. 6 is a schematic plan view illustrating a portion of the display region of the display panel according to an embodiment. FIGS. 7A and 7B are enlarged schematic plan views illustrating portions of the display region of the display panel according to embodiments. FIG. 7A is an enlarged schematic view illustrating a pixel unit PXU of the display region of the display panel, and FIG. 7B is an enlarged schematic view illustrating an arrangement of one light emitting region and one sensing region included in the pixel unit. Referring to FIGS. 3, 6, 7A, and 7B, the active region DA may include a non-light emitting region NPXA, light emitting regions PXA-R, PXA-G, and PXA-B, and a sensing region SA. The light emitting regions PXA-R, PXA-G, and PXA-B may be regions from which light generated from light emitting elements is emitted. The light emitting regions PXA-R, PXA-G, and PXA-B may be spaced apart from each other in plan view. The sensing region SA may be a region in which a light sensing element obtains fingerprint information of the user. The sensing region SA may be spaced apart from the light emitting regions PXA-R, PXA-G, and PXA-B in plan view.

The light emitting regions PXA-R, PXA-G, and PXA-B and the sensing region SA may be regions separated from each other by the pixel defining layer PDL (refer to FIG. 5). The non-light emitting region NPXA may be positioned between the light emitting regions PXA-R, PXA-G, and PXA-B and the sensing region SA, and may be a region corresponding to the pixel defining layer PDL. For example, in the disclosure, each of the light emitting regions PXA-R, PXA-G, and PXA-B and the sensing region SA may correspond to a pixel.

In the display panel DP of an embodiment, the light emitting regions PXA-R, PXA-G, and PXA-B may be divided into a plurality of groups according to the colors of light generated from the light emitting elements. In the active region DA of an embodiment illustrated in FIGS. 6, 7A, and 7B, three light emitting regions PXA-R, PXA-G, and PXA-B that emit red light, green light, and blue light, respectively, are illustrated as an example. The display panel DP of an embodiment may include the red light emitting region PXA-R, the green light emitting region PXA-G, and the blue light emitting region PXA-B separated from each other. The red light emitting region (e.g., single red light emitting region) PXA-R, the green light emitting region (e.g., single green light emitting region) PXA-G, the blue light emitting region (e.g., single blue light emitting region) PXA-B, and the sensing region (e.g., single sensing region) SA, which are disposed adjacent to each other, may be grouped as a pixel unit (e.g., single pixel unit) PXU.

The light emitting elements corresponding to the light emitting regions PXA-R, PXA-G, and PXA-B, respectively, may emit light having different wavelength ranges. The display panel DP of an embodiment may include a red light emitting element that emits red light and corresponds to the red light emitting region PXA-R, a green light emitting element that emits green light and corresponds to the green light emitting region PXA-G, and a blue light emitting element that emits blue light and corresponds to the blue light emitting region PXA-B. For example, the red light emitting region PXA-R may emit light having a wavelength range of about 620 nm to about 700 nm, the green light emitting region PXA-G may emit light having a wavelength range of about 500 nm to about 600 nm, and the blue light emitting region PXA-B may emit light having a wavelength range of about 410 nm to about 480 nm.

The light emitting elements corresponding to the light emitting regions PXA-R, PXA-G, and PXA-B, respectively, may emit light having the same wavelength range, or at least one of the light emitting elements may emit light having a wavelength range different from the wavelength range in which the remaining light emitting elements emit light. For example, the light emitting elements corresponding to the light emitting regions PXA-R, PXA-G, and PXA-B, respectively, may all emit blue light.

In the display panel DP according to an embodiment, the light emitting regions PXA-R, PXA-G, and PXA-B and the sensing region SA may be arranged in a stripe form. Referring to FIG. 6, red light emitting regions PXA-R may be arranged in the second direction DR2, green light emitting regions PXA-G may be arranged in the second direction DR2, and blue light emitting regions PXA-B may be arranged in the second direction DR2. For example, the light emitting regions PXA-R, PXA-G, and PXA-B may be alternately arranged in the first direction DR1 in the order of the red light emitting region PXA-R, the green light emitting region PXA-G, and the blue light emitting region PXA-B. For example, sensing regions SA may be arranged in the second direction DR2 in a form in which each of the sensing regions SA is surrounded by the green light emitting region PXA-G. The display panel DP according to an embodiment may include a first pixel column PXL1 in which the red light emitting regions PXA-R are arranged in the second direction DR2, a second pixel column PXL2 in which the green light emitting regions PXA-G and the sensing regions SA are arranged in the second direction DR2, and a third pixel column PXL3 in which the blue light emitting regions PXA-B are arranged in the second direction DR2.

In the display panel DP according to an embodiment, the light emitting regions PXA-R, PXA-G, and PXA-B and the sensing region SA may have a rectangular shape in plan view. However, embodiments are not limited thereto, the light emitting regions PXA-R, PXA-G, and PXA-B and the sensing region SA may have a rounded rectangular shape.

In the display panel DP according to an embodiment, the sensing region SA may be at least partially surrounded by one of the light emitting regions PXA-R, PXA-G, and PXA-B in plan view. As illustrated in FIGS. 6, 7A, and 7B, the sensing region SA may be at least partially surrounded by the green light emitting region PXA-G in plan view. For example, the expression “region A is surrounded by region B on a plane (or in plan view)” used herein means that region B is disposed adjacent to more than half of the periphery of region A and region A is disposed inside region B. The sensing region SA may be disposed inside the region in which the green light emitting region PXA-G is disposed in plan view. In the disclosure, the light emitting region surrounding at least a portion of the sensing region SA may be referred to as the “first light emitting region”. In the embodiment illustrated in FIGS. 6, 7A, and 7B, the green light emitting region PXA-G may correspond to the first light emitting region.

Referring to FIGS. 7A and 7B, the sensing region SA may have a rectangular shape having a first side SS1 and a second side SS2 that extend in the first direction DR1 in plan view and a third side SS3 and a fourth side SS4 that extend in the second direction DR2 in plan view. The green light emitting region PXA-G surrounding at least a portion of the sensing region SA may surround at least three sides of the sensing region SA having a rectangular shape. As illustrated in FIG. 7B, the green light emitting region PXA-G may surround the entirety of the first side SS1, the third side SS3, and the fourth side SS4 of the sensing region SA. However, embodiments are not limited thereto, the green light emitting region PXA-G may have a shape that does not surround at least a portion of the third side SS3 and at least a portion of the fourth side SS4 of the sensing region SA.

As illustrated in FIGS. 7A and 7B, the green light emitting region PXA-G may not surround a portion of the sensing region SA having a rectangular shape. The green light emitting region PXA-G may surround three sides of the sensing region SA, and may not surround at least a portion of the remaining one side of the sensing region SA. The green light emitting region PXA-G may not surround at least a portion of the second side SS2 of the sensing region SA. For example, among the regions adjacent to the sensing region SA, a portion of the non-light emitting region NPXA, which is not surrounded by the green light emitting region PXA-G, may correspond to a wiring region SLA. Wiring and an electrode included in the sensor drive circuit O_SD (refer to FIG. 4) for driving the light sensing element OPD (refer to FIG. 5) may be disposed in the wiring region SLA adjacent to the sensing region SA.

The sensing region SA may have a smaller area (or smaller size) than the light emitting regions PXA-R, PXA-G, and PXA-B in plan view. The sensing region SA may have a smaller area (or smaller size) than the red light emitting region PXA-R and the blue light emitting region PXA-B. The sensing region SA may have a smaller area (or smaller size) than the green light emitting region PXA-G surrounding at least a portion of the sensing region SA.

The area (or size) of the green light emitting region PXA-G surrounding the sensing region SA may be smaller than the areas (or sizes) of the other light emitting regions. For example, the area (or size) of the green light emitting region PXA-G may be smaller than the areas (or sizes) of the red light emitting region PXA-R and the blue light emitting region PXA-B.

The sum of the area (or size) of the sensing region SA and the area (or size) of the green light emitting region PXA-G surrounding at least a portion of the sensing region SA may be designed to correspond to the areas (or sizes) of the other light emitting regions. For example, the sum of the area (or size) of the sensing region SA and the area (or size) of the green light emitting region PXA-G may be substantially the same as the area (or size) of each of the red light emitting region PXA-R and the blue light emitting region PXA-B. The expression “the areas (or sizes) of two regions are ‘substantially the same’ as each other” used herein includes not only the case in which the areas are physically equal but also the case in which there is a difference between the areas (or sizes) at a level of an error that occurs in a process despite the same design. As the sum of the area (or size) of the sensing region SA and the area (or size) of the green light emitting region PXA-G is substantially the same as the area (or size) of each of the red light emitting region PXA-R and the blue light emitting region PXA-B, the sum of the opening ratio of the sensing region SA and the opening ratio of the green light emitting region PXA-G may be substantially the same as the opening ratio of each of the red light emitting region PXA-R and the blue light emitting region PXA-B.

The green light emitting region PXA-G, the red light emitting region PXA-R, and the blue light emitting region PXA-B may have substantially the same width in the first direction DR1. In an embodiment, the green light emitting region PXA-G may have a first width d1 in the first direction DR1 the red light emitting region PXA-R may have a second width d2 in the first direction DR1, and the blue light emitting region PXA-B may have a third width d3 in the first direction DR1. The first width d1, the second width d2, and the third width d3 may be substantially equal to each other.

The length of the green light emitting region PXA-G in the second direction DR2 may be greater than the lengths of the red light emitting region PXA-R and the blue light emitting region PXA-B in the second direction DR2. In an embodiment, the green light emitting region PXA-G may have a first length L1 in the second direction DR2, the red light emitting region PXA-R may have a second length L2 in the second direction DR2, and the first length L1 may be greater than the second length L2. As the green light emitting region PXA-G has the sensing region SA disposed in the green light emitting region PXA-G and therefore has a lower opening ratio than the red light emitting region PXA-R and the blue light emitting region PXA-B, the green light emitting region PXA-G may be longer in the second direction DR2 than the red light emitting region PXA-R and the blue light emitting region PXA-B to compensate for the low opening ratio of the green light emitting region PXA-G. For example, as the green light emitting region PXA-G is longer in the second direction DR2 than the red light emitting region PXA-R, a lower side G-L of the green light emitting region PXA-G may be provided in a lower position than a lower side R-L of the red light emitting region PXA-R based on the second direction DR2.

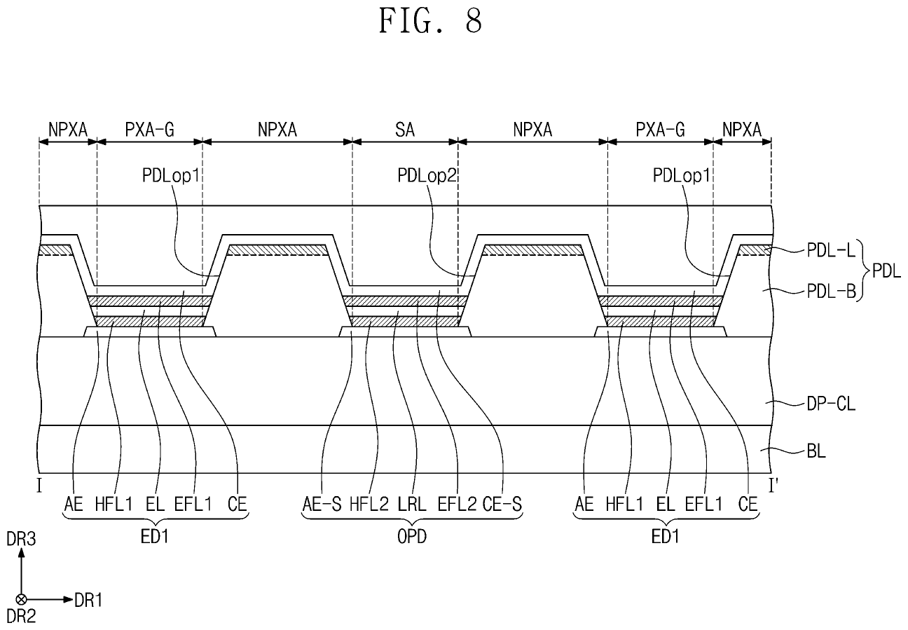

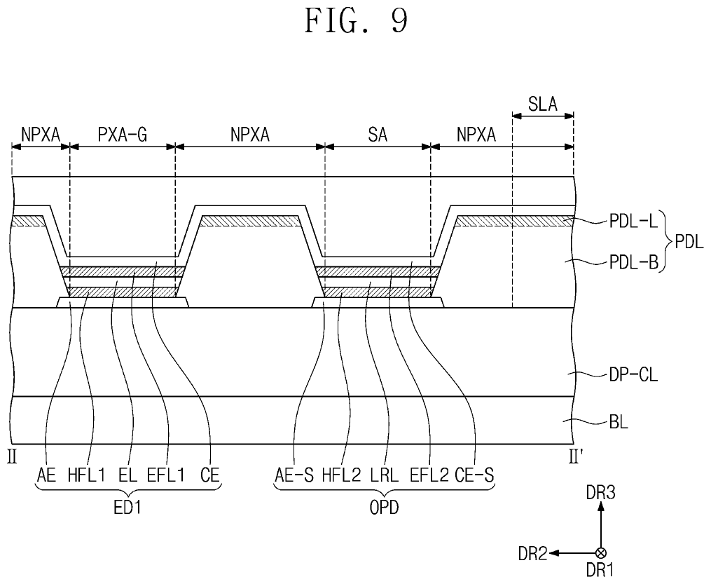

FIGS. 8 and 9 are schematic sectional views of a portion of the display region of the display panel. FIG. 8 illustrates a section corresponding to line I-I′ of FIG. 7B, and FIG. 9 illustrates a section corresponding to line II-II′ of FIG. 7B.

Referring to FIGS. 7B, 8, and 9 together, the sensing region SA may be at least partially surrounded by the green light emitting region PXA-G in plan view. As illustrated in FIG. 8, on the section defined by the first direction DR1 and the third direction DR3, the sensing region SA may be disposed inside the green light emitting region PXA-G based on the first direction DR1. As illustrated in FIG. 9, on the section defined by the second direction DR2 and the third direction DR3, the green light emitting region PXA-G may be disposed on a side of the sensing region SA based on the second direction DR2. For example, on the section defined by the second direction DR2 and the third direction DR3, the wiring region SLA may be disposed on an opposite side of the sensing region SA based on the second direction DR2.

A first light emitting element ED1 may be disposed to correspond to the green light emitting region PXA-G, and a light sensing element OPD may be disposed to correspond to the sensing region SA. The first light emitting element ED1 may be disposed in a first opening PDLop1 provided in the pixel defining layer PDL. The light sensing element OPD may be disposed in a second opening PDLop2 provided in the pixel defining layer PDL. The first opening PDLop1 may define the green light emitting region PXA-G, and the second opening PDLop2 may define the sensing region SA. The first opening PDLop1 may surround at least a portion of the second opening PDLop2 in plan view.

The first light emitting element ED1 may include a first electrode AE, a first hole control layer HFL1, a light emitting layer EL, a first electron control layer EFL1, and a second electrode CE. The light sensing element OPD may include a first electrode AE-S, a second hole control layer HFL2, a photoelectric conversion layer LRL, a second electron control layer EFL2, and a second electrode CE-S. In the disclosure, the first hole control layer HFL1 and the first electron control layer EFL1 may be referred to as the “first functional layer”. In the disclosure, the second hole control layer HFL2 and the second electron control layer EFL2 may be referred to as the “second functional layer”.

The first hole control layer HFL1 and the second hole control layer HFL2 may include a hole transport material. The first hole control layer HFL1 may include a hole injection layer adjacent to the first electrode AE and a hole transport layer disposed between the hole injection layer and the light emitting layer EL, and the second hole control layer HFL2 may include a hole injection layer adjacent to the first electrode AE-S and a hole transport layer disposed between the hole injection layer and the photoelectric conversion layer LRL.

The first electron control layer EFL1 and the second electron control layer EFL2 may include an electron transport material. The first electron control layer EFL1 may include an electron injection layer adjacent to the second electrode CE and an electron transport layer disposed between the electron injection layer and the light emitting layer EL, and the second electron control layer EFL2 may include an electron injection layer adjacent to the second electrode CE-S and an electron transport layer disposed between the electron injection layer and the photoelectric conversion layer LRL.

The first hole control layer HFL1, the light emitting layer EL, and the first electron control layer EFL1 included in the first light emitting element ED1 may be subjected to patterning and disposed in the first opening PDLop1. The second hole control layer HFL2, the photoelectric conversion layer LRL, the second electron control layer EFL2 included in the light sensing element OPD may be subjected to patterning and disposed in the second opening PDLop2.

The pixel defining layer PDL may include a barrier wall portion PDL-B, which is disposed on the base layer BL and the circuit layer DP-CL, and a liquid-repellent portion PDL-L disposed on the barrier wall portion PDL-B. The liquid-repellent portion PDL-L may be disposed at the top (or upper portion) of the pixel defining layer PDL, and an upper surface of the liquid-repellent portion PDL-L may define an upper surface of the pixel defining layer PDL.

The liquid-repellent portion PDL-L may include a liquid-repellent organic material. The liquid-repellent portion PDL-L may include a liquid-repellent material, and may have liquid-repellent characteristics. For example, the liquid-repellent portion PDL-L may include a fluorine-containing organic material, and may have liquid-repellent characteristics. The liquid-repellent portion PDL-L may include a liquid-repellent material such as a perfluoropolyether (PFPE) derivative. As the liquid-repellent portion PDL-L is disposed at the top (or upper portion) of the pixel defining layer PDL, a process of forming the first functional layer included in the first light emitting element ED1 and the second functional layer included in the light sensing element OPD may be performed in a step. Detailed description thereabout will be given below.

The encapsulation layer TFE may be disposed on the first light emitting element ED1 and the light sensing element OPD, and may cover the first light emitting element ED1 and the light sensing element OPD. The encapsulation layer TFE may include at least an inorganic layer or an organic layer. In an embodiment, the encapsulation layer TFE may include two inorganic layers and an organic layer disposed between the two inorganic layers. In an embodiment, the encapsulation layer may include inorganic layers and organic layers that are alternately stacked with each other.

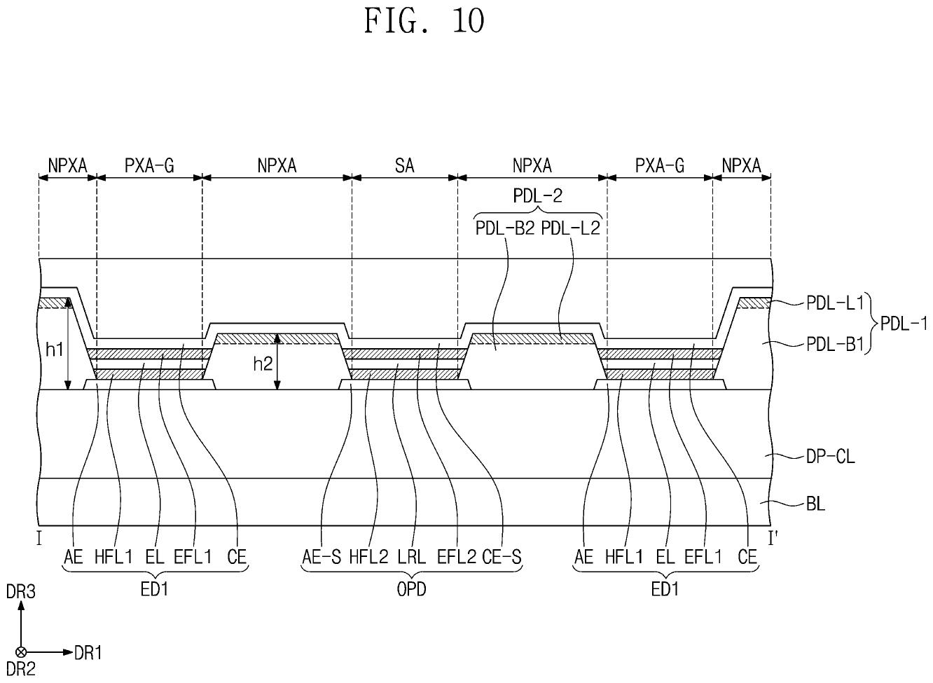

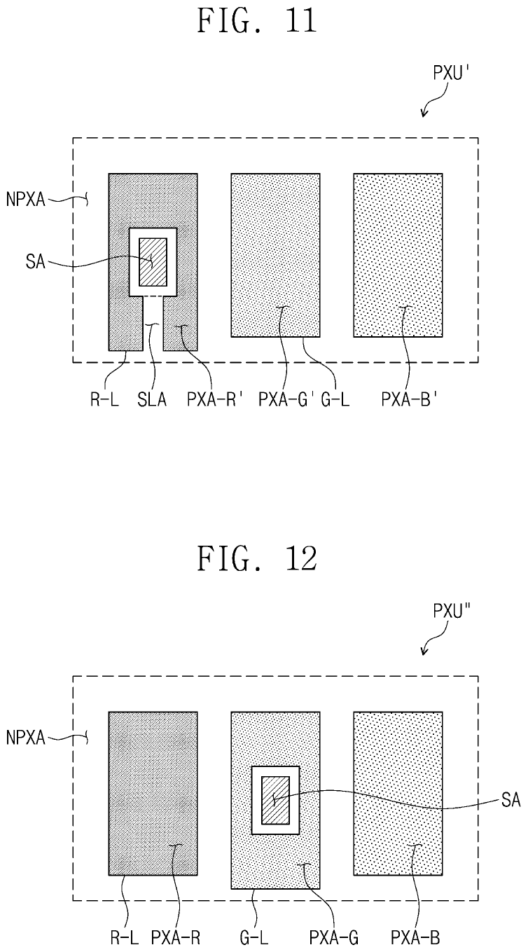

FIG. 10 is a schematic sectional view of a portion of the display region of the display panel. FIG. 10 illustrates a section corresponding to line I-I′ of FIG. 7B. For example, in FIG. 10, a section of the display panel according to an embodiment is illustrated on a section corresponding to FIG. 8.

Referring to FIGS. 7A, 7B, and 10, the pixel defining layer PDL may include a first pixel defining portion PDL-1 disposed between the light emitting regions PXA-R, PXA-G, and PXA-B and a second pixel defining portion PDL-2 disposed between the green light emitting region PXA-G and the sensing region SA. The first pixel defining portion PDL-1 may be spaced apart from the sensing region SA with the green light emitting region PXA-G, which is between the first pixel defining portion PDL-1 and the sensing region SA.

The first pixel defining portion PDL-1 and the second pixel defining portion PDL-2 may include barrier wall portions PDL-B1 and PDL-B2 and liquid-repellent portions PDL-L1 and PDL-L2 disposed on the barrier wall portions PDL-B1 and PDL-B2, respectively. The first pixel defining portion PDL-1 may include the first barrier wall portion PDL-B1 and the first liquid-repellent portion PDL-L1. The second pixel defining portion PDL-2 may include the second barrier wall portion PDL-B2 and the second liquid-repellent portion PDL-L2.

The first pixel defining portion PDL-1 and the second pixel defining portion PDL-2 may have different heights on the section. The first pixel defining portion PDL-1 may have a first height h1 in the third direction DR3, and the second pixel defining portion PDL-2 may have a second height h2 in the third direction DR3. The first height h1 may be greater than the second height h2. In an embodiment, the second height h2 may be about 30% to about 70% of the first height h1. As the second height h2 is smaller than the first height h1, the forming process of the first functional layer and the second functional layer, which is performed in a step, may be smoothly performed.

FIGS. 11 and 12 are enlarged schematic plan views illustrating portions of the display region of the display panel according to embodiments. In FIGS. 11 and 12, sections of pixel units PXU′ and PXU″ according to embodiments are illustrated on a plane corresponding to FIG. 7A.

Referring to FIG. 11, unlike that illustrated in FIG. 7A, in the pixel unit (e.g., single pixel unit) PXU′, a sensing region SA may be surrounded by a red light emitting region PXA-R′ rather than a green light emitting region PXA-G′ (or blue light emitting region PXA-B′). The sensing region SA may be disposed inside the red light emitting region PXA-R′. The red light emitting region PXA-R′ may surround at least a portion of the sensing region SA. The red light emitting region PXA-R′ may surround at least three sides of the sensing region SA having a rectangular shape. A wiring region SLA may be disposed adjacent to a second side SS2 (refer to FIG. 7B) of the sensing region SA that is not surrounded by the red light emitting region PXA-R′. For example, as the sensing region SA is disposed inside the red light emitting region PXA-R′ rather than the green light emitting region PXA-G′ (or blue light emitting region PXA-B′), a lower side R-L of the red light emitting region PXA-R′ may be provided in a lower position (or positioned lower) than a lower side G-L of the green light emitting region PXA-G′ (or blue light emitting region PXA-B′) based on the second direction DR2.

Referring to FIG. 12, unlike that illustrated in FIG. 7A, in the pixel unit PXU″, a sensing region SA may be entirely surrounded by a green light emitting region PXA-G. For example, the sensing region SA may be completely surrounded by the green light emitting region PXA-G, and the separate wiring region SLA (refer to FIG. 7A) may not be provided. The green light emitting region PXA-G may surround all of four sides of the sensing region SA having a rectangular shape.

In a display panel of an embodiment, a sensing region having a light sensing element disposed in the sensing region may be at least partially surrounded by one of light emitting regions having light emitting elements disposed in the light emitting regions. For example, the sensing region may be disposed inside one of the light emitting regions. In an embodiment, the sensing region may be at least partially surrounded by a green or red light emitting region that emits light having a relatively wide wavelength range. As the sensing region is at least partially surrounded by one of the light emitting regions in the display panel according to an embodiment, a separate pixel column, in which the sensing region is disposed, may not be required. Accordingly, the separation gap between the light emitting regions in plan view may be minimized, and thus the display panel having excellent resolution may be provided.

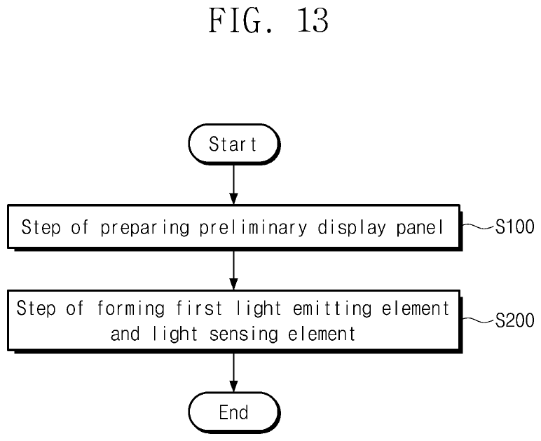

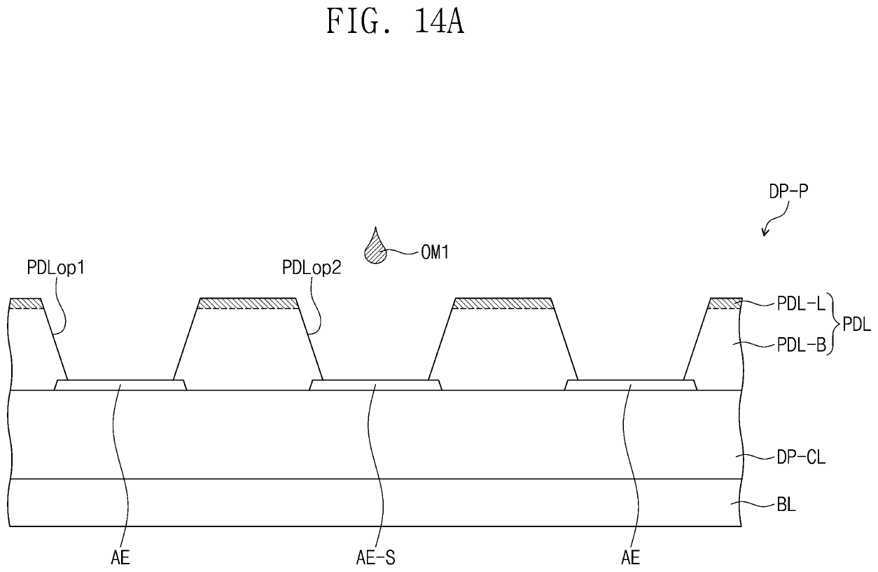

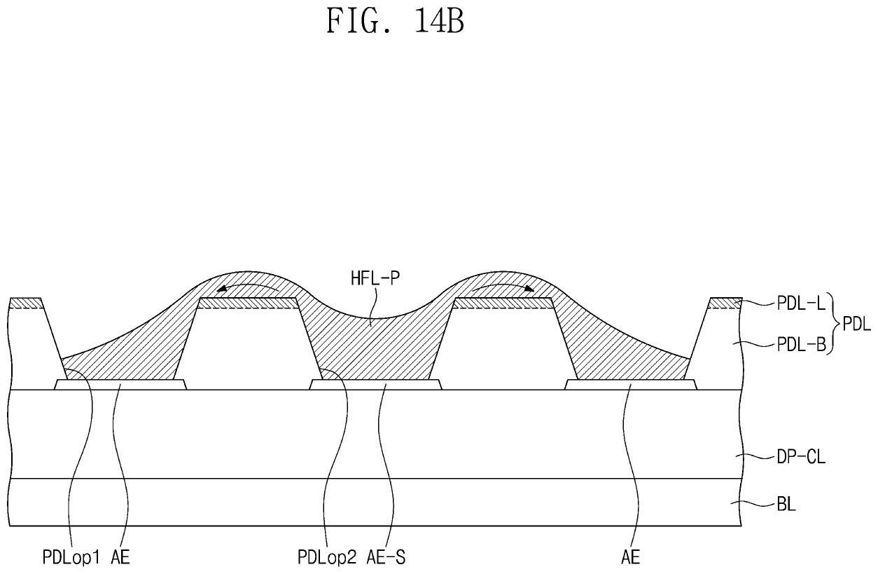

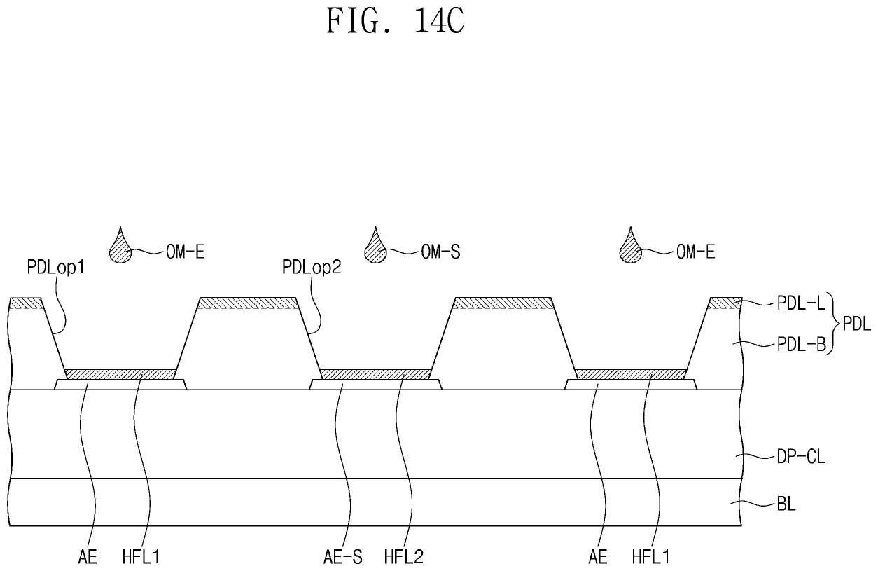

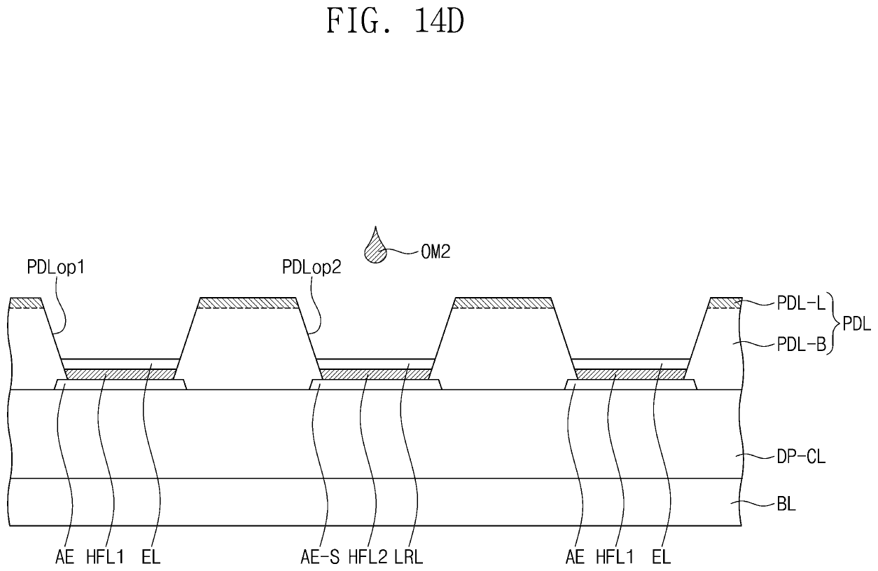

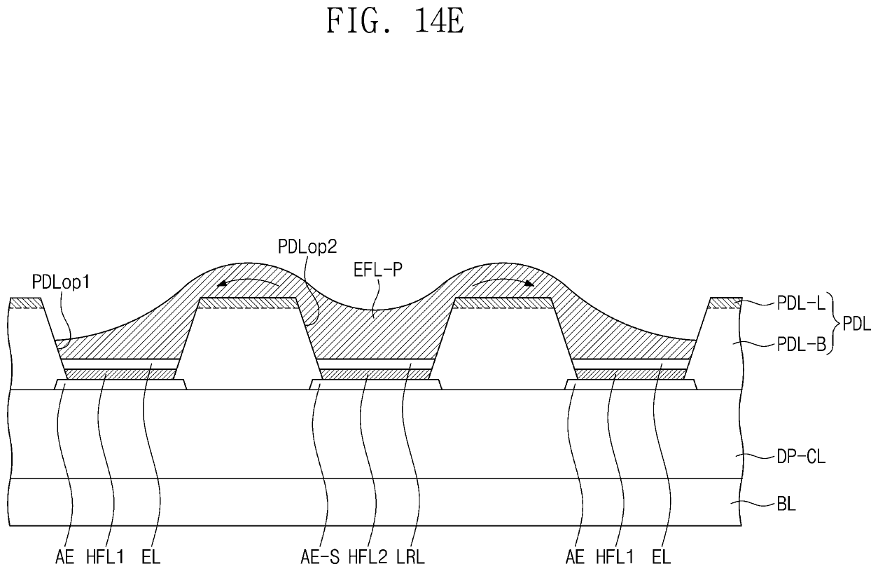

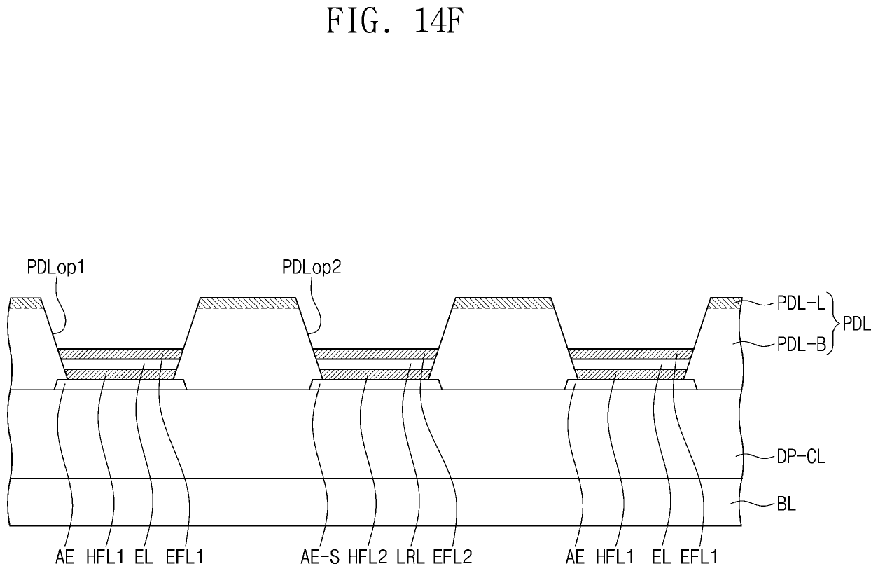

FIG. 13 is a flowchart illustrating a display panel manufacturing method according to an embodiment. FIGS. 14A, 14B, 14C, 14D, 14E, and 14F are schematic sectional views illustrating steps of the display panel manufacturing method according to an embodiment. In each of FIGS. 14A, 14B, 14C, 14D, 14E, and 14F, steps of the display panel manufacturing method are illustrated in the section illustrated in FIG. 8.

Referring to FIG. 13, the display panel manufacturing method according to an embodiment may include a step S100 of preparing a preliminary display panel including the base layer and the pixel defining layer and a step S200 of forming the first light emitting element and the light sensing element by providing organic materials on the preliminary display panel.

Referring to FIGS. 13 and 14A, the preliminary display panel DP-P may include the base layer BL, the circuit layer DP-CL, and the pixel defining layer PDL. The pixel defining layer PDL may have the first opening PDLop1 and the second opening PDLop2 defined (or formed) in pixel defining layer PDL. The first opening PDLop1 may define the light emitting region PXA (refer to FIG. 5) in the display panel manufactured by the display panel manufacturing method, and the second opening PDLop2 may define the sensing region SA (refer to FIG. 5) in the display panel manufactured by the display panel manufacturing method.

For example, the pixel defining layer PDL may include the barrier wall portion PDL-B that is disposed on the base layer BL and the circuit layer DP-CL and the liquid-repellent portion PDL-L disposed on the barrier wall portion PDL-B. The liquid-repellent portion PDL-L may be disposed at the top (or upper portion) of the pixel defining layer PDL, and the upper surface of the liquid-repellent portion PDL-L may define the upper surface of the pixel defining layer PDL. The liquid-repellent portion PDL-L may include a liquid-repellent organic material. The liquid-repellent portion PDL-L may include a fluorine-containing organic material, and may have liquid-repellent characteristics.

In the display panel manufacturing method, a step of providing organic materials OM1 and OM2 on the prepared preliminary display panel DP-P to form the first functional layer and the second functional layer may be performed. The first functional layer included in the light emitting element ED (refer to FIG. 5) and the second functional layer included in the light sensing element OPD (refer to FIG. 5) may be formed by the step of providing the organic materials OM1 and OM2. Hereinafter, a step of forming the light emitting element ED and the light sensing element, which includes the step of forming the first functional layer and the second functional layer, will be described in more detail.

Referring to FIGS. 14A, 14B, and 14C, the first organic material OM1 may be provided on the prepared preliminary display panel DP-P. The first organic material OM1 may include a hole transport material. The first organic material OM1 may be provided on the preliminary display panel DP-P by a printing process rather than a deposition process. For example, the first organic material OM1 may be provided by an ink-jet printing process.

The first organic material OM1 may be provided in the second opening PDLop2 defined in the pixel defining layer PDL. The first organic material OM1 may be provided to a central portion of the sensing region SA (refer to FIG. 8) of the display panel DP-P that is defined by the second opening PDLop2, and may be provided in excess to fill and overflow the second opening PDLop2. Thereafter, as illustrated in FIG. 14B, the first organic material OM1 provided in the second opening PDLop2 may form a first preliminary functional layer HFL-P. The first preliminary functional layer HFL-P may overflow the second opening PDLop2 toward the outside, and may fill the first opening PDLop1 surrounding at least a portion of the second opening PDLop2.

As the liquid-repellent portion PDL-L is disposed at the top (or upper portion) of the pixel defining layer PDL, the overflowing first preliminary functional layer HFL-P may fill the first opening PDLop1 and may not remain on the pixel defining layer PDL. Thereafter, the first preliminary functional layer HFL-P may be dried, and the first hole control layer HFL1 disposed in the first opening PDLop1 and the second hole control layer HFL2 disposed in the second opening PDLop2 may be formed. As the first hole control layer HFL1 and the second hole control layer HFL2 are formed of the same first organic material OM1, the first hole control layer HFL1 and the second hole control layer HFL2 may include the same material, and may be formed by the same process.

Referring to FIGS. 14C and 14D, after the first hole control layer HFL1 and the second hole control layer HFL2 are formed, the light emitting layer EL and the photoelectric conversion layer LRL may be formed by providing a light emitting material OM-E and a light sensing material OM-S. The light emitting material OM-E and the light sensing material OM-S may be provided by a printing process. The light emitting material OM-E and the light sensing material OM-S may be provided by an ink-jet printing process. Unlike the first organic material OM1, the light emitting material OM-E and the light sensing material OM-S may be separately provided in the respective openings. The light emitting material OM-E may be subjected to patterning and provided in the first opening PDLop1, and the light sensing material OM-S may be subjected to patterning and provided in the second opening PDLop2.

Referring to FIGS. 14D, 14E, and 14F, the second organic material OM2 may be provided after the light emitting layer EL and the photoelectric conversion layer LRL are formed. The second organic material OM2 may include an electron transport material. The second organic material OM2 may be provided on the photoelectric conversion layer LRL by a printing process rather than a deposition process. For example, the second organic material OM2 may be provided by an ink-jet printing process.

The second organic material OM2 may be provided in the second opening PDLop2 defined in the pixel defining layer PDL. The second organic material OM2 may be provided to the central portion of the sensing region SA (refer to FIG. 8) of the display panel that is defined by the second opening PDLop2, and may be provided in excess to fill and overflow the second opening PDLop2. Thereafter, as illustrated in FIG. 14E, the second organic material OM2 provided in the second opening PDLop2 may form a second preliminary functional layer EFL-P. The second preliminary functional layer EFL-P may overflow the second opening PDLop2 toward the outside, and may fill the first opening PDLop1 surrounding at least a portion of the second opening PDLop2.

As the liquid-repellent portion PDL-L is disposed at the top (or upper portion) of the pixel defining layer PDL, the overflowing second preliminary functional layer EFL-P may fill the first opening PDLop1 and may not remain on the pixel defining layer PDL. Thereafter, the second preliminary functional layer EFL-P may be dried, and the first electron control layer EFL1 disposed in the first opening PDLop1 and the second electron control layer EFL2 disposed in the second opening PDLop2 may be formed. As the first electron control layer EFL1 and the second electron control layer EFL2 are formed of the same second organic material OM2, the first electron control layer EFL1 and the second electron control layer EFL2 may include the same material, and may be formed by the same process.

After the step of forming the first electron control layer EFL1 and the second electron control layer EFL2, the second electrodes CE and CE-S(refer to FIG. 8) may be formed on the first electron control layer EFL1 and the second electron control layer EFL2. The second electrodes may be provided in the form of a common electrode on the first electron control layer EFL1, the second electron control layer EFL2, and the pixel defining layer PDL.

In the display panel manufacturing method, the second opening PDLop2 in which the light sensing element OPD is disposed in the manufactured display panel may be at least partially surrounded by the first opening in which the light emitting element ED is disposed. Through this shape, in the display panel manufacturing method, the functional layer included in the light sensing element OPD and the functional layer of the light emitting element ED may be formed by the same process through a step in case that the functional layers such as the hole control layer and the electron control layer are formed. Accordingly, process steps required in case that the functional layer included in the light sensing element OPD and the functional layer of the light emitting element ED are formed by separate processes may be omitted. Thus, the process may be simplified, and process time and cost may be reduced.

For example, the display panel DP may include the light emitting regions PXA-R, PXA-G, and PXA-B (refer to FIG. 7A), and as described above, the sum of the area (or size) of the sensing region SA and the area (or size) of the light emitting region (e.g., the green light emitting region PXA-G) surrounding at least a portion of the sensing region SA may be designed to correspond to the areas of the other light emitting regions. Accordingly, the number (or amounts) of drops of the organic materials OM1 and OM2 that form the first functional layer and the second functional layer, respectively, may be substantially the same as the number (or amounts) of drops of organic materials that form the functional layers of the other light emitting regions (e.g., the red light emitting region PXA-R or the blue light emitting region PXA-B).

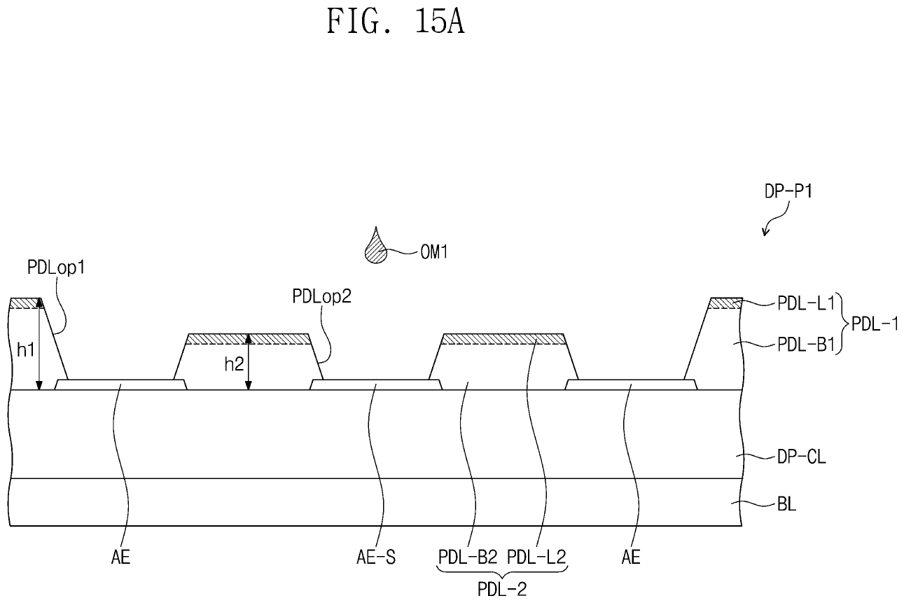

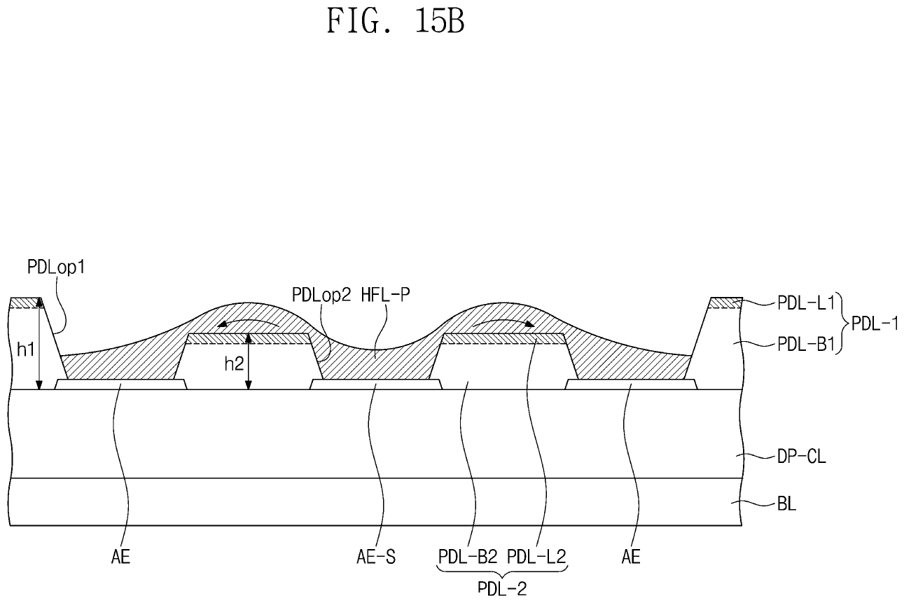

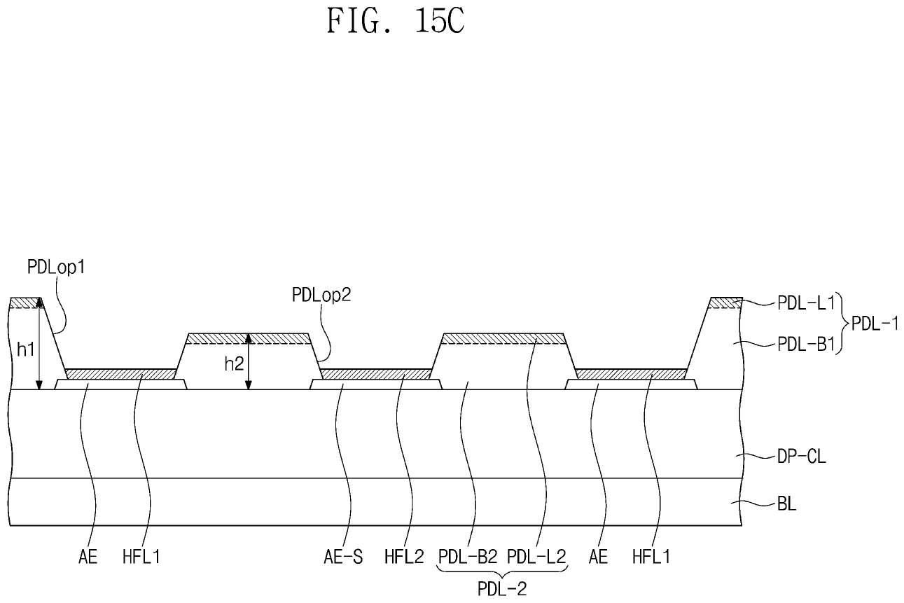

FIGS. 15A, 15B, and 15C are schematic sectional views illustrating steps of a display panel manufacturing method according to an embodiment. In FIGS. 15A, 15B, and 15C, steps corresponding to the steps on the sections illustrated in FIGS. 14A, 14B, and 14C are illustrated.

Referring to FIGS. 15A, 15B, and 15C, the pixel defining layer PDL included in a preliminary display panel DP-P1 may include the first pixel defining portion PDL-1 and the second pixel defining portion PDL-2. The first pixel defining portion PDL-1 may be adjacent to the first opening PDLop1, and may be spaced apart from the second opening PDLop2. The second pixel defining portion PDL-2 may be disposed between the first opening PDLop1 and the second opening PDLop2. The first pixel defining portion PDL-1 and the second pixel defining portion PDL-2 may have different heights on the section. The first pixel defining portion PDL-1 may have the first height h1 in the third direction DR3, and the second pixel defining portion PDL-2 may have the second height h2 in the third direction DR3. The first height h1 may be greater than the second height h2. In an embodiment, the second height h2 may be in a range of about 30% to about 70% of the first height h1.

In the display panel manufacturing method, a first organic material OM1 may be provided on the prepared preliminary display panel DP-P1. The first organic material OM1 may be provided by an ink-jet printing process.

The first organic material OM1 may be provided in the second opening PDLop2 defined in the pixel defining layer PDL. The first organic material OM1 may be provided to the central portion of the sensing region SA (refer to FIG. 8) of the display panel DP-P1 that is defined by the second opening PDLop2, and may be provided in excess to fill and overflow the second opening PDLop2. Thereafter, as illustrated in FIG. 15B, the first organic material OM1 provided in the second opening PDLop2 may form a first preliminary functional layer HFL-P. The first preliminary functional layer HFL-P may overflow the second opening PDLop2 toward the outside, and may fill the first opening PDLop1 surrounding at least a portion of the second opening PDLop2.

For example, as the second pixel defining portion PDL-2 adjacent to the second opening PDLop2 has the relatively small second height h2, the first preliminary functional layer HFL-P may more readily overflow the second pixel defining portion PDL-2. For example, in the display panel manufacturing method, the height of the second pixel defining portion PDL-2 may be formed to be small such that the first organic material OM1 provided in the second opening PDLop2 readily overflows toward the first opening PDLop1.

The overflowing first preliminary functional layer HFL-P may fill the first opening PDLop1 and may not remain on the pixel defining layer PDL. Thereafter, the first preliminary functional layer HFL-P may be dried, and the first hole control layer HFL1 disposed in the first opening PDLop1 and the second hole control layer HFL2 disposed in the second opening PDLop2 may be formed. As the first hole control layer HFL1 and the second hole control layer HFL2 are formed of the same first organic material OM1, the first hole control layer HFL1 and the second hole control layer HFL2 may include the same material, and may be formed by the same process.

According to the embodiments, a separate pixel column in which a sensing region is disposed may be omitted. Accordingly, the separation gap between the light emitting regions in the display panel DP may be minimized.

According to the embodiments, the functional layer included in the light sensing element OPD and the functional layer of the light emitting element ED may be formed by a process (e.g., single process). Accordingly, the display panel manufacturing method may reduce process time and cost.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display panel comprising:
a base layer including a plurality of light emitting regions and a sensing region spaced apart from each other in plan view;
a plurality of light emitting elements disposed on the base layer and overlapping the plurality of light emitting regions, respectively; and
a light sensing element disposed on the base layer and overlapping the sensing region, wherein
the plurality of light emitting regions include a first light emitting region that emits light having a first wavelength, and
at least a portion of the sensing region is surrounded by the first light emitting region in plan view.

2. The display panel of claim 1, wherein
in a first direction, the sensing region is disposed between portions of the first light emitting region, and
in a second direction intersecting the first direction, the sensing region is adjacent to at least one side of the first light emitting region.

3. The display panel of claim 1, wherein
the sensing region has a rectangular shape including sides extending in a first direction and a second direction intersecting the first direction, and
the first light emitting region surrounds at least three sides of the sensing region.

4. The display panel of claim 1, wherein the plurality of light emitting regions further include:
a second light emitting region that emits light having a second wavelength different from the first wavelength; and
a third light emitting region that emits light having a third wavelength different from the first wavelength and the second wavelength.

5. The display panel of claim 4, wherein a sum of an area of the first light emitting region and an area of the sensing region is substantially the same as an area of the second light emitting region.

6. The display panel of claim 4, wherein a length of the first light emitting region in a direction is greater than a length of the second light emitting region in the direction.

7. The display panel of claim 4, wherein
the first light emitting region includes a plurality of first light emitting regions,
the second light emitting region includes a plurality of second light emitting regions,
the third light emitting region includes a plurality of third light emitting regions,
the plurality of first light emitting regions are arranged side by side in a direction,
the plurality of second light emitting regions are arranged side by side in the direction, and
the plurality of third light emitting regions are arranged side by side in the direction.

8. The display panel of claim 1, wherein an area of the sensing region is smaller than an area of the first light emitting region.

9. The display panel of claim 1, wherein
the sensing region includes a first side and a second side extending in a first direction and a third side and a fourth side extending in a second direction intersecting the first direction, and
the first light emitting region surrounds the first side, the third side, and the fourth side, and does not surround at least a portion of the second side.

10. The display panel of claim 1, wherein the light having the first wavelength is light having a green wavelength range.

11. The display panel of claim 1, wherein the light having the first wavelength is light having a red wavelength range.

12. The display panel of claim 1, further comprising:
a pixel defining layer disposed on the base layer, the pixel defining layer having a plurality of openings,
wherein the plurality of openings define the plurality of light emitting regions and the sensing region, respectively.

13. The display panel of claim 12, wherein the pixel defining layer includes:
a barrier wall portion disposed on the base layer; and
a liquid-repellent portion disposed on the barrier wall portion, the liquid-repellent portion including a liquid-repellent organic material.

14. The display panel of claim 12, wherein
the pixel defining layer includes:
a first pixel defining portion disposed between the plurality of light emitting regions; and
a second pixel defining portion disposed between the first light emitting region and the sensing region, and
a height of the second pixel defining portion is smaller than a height of the first pixel defining portion.

15. The display panel of claim 1, wherein
the plurality of light emitting elements include a first light emitting element overlapping the first light emitting region,
the first light emitting element includes:
a first light emitting electrode disposed on the base layer;
a second light emitting electrode disposed over the first light emitting electrode; and
a first functional layer disposed between the first light emitting electrode and the second light emitting electrode,
the light sensing element includes:
a first light sensing electrode disposed on the base layer;
a second light sensing electrode disposed over the first light sensing electrode; and
a second functional layer disposed between the first light sensing electrode and the second light sensing electrode, and
the first functional layer and the second functional layer include a same material.

16. A display panel comprising:
a base layer including a first light emitting region and a sensing region spaced apart from each other in plan view;
a pixel defining layer disposed on the base layer, the pixel defining layer having a first opening defining the first light emitting region and a second opening defining the sensing region;
a first light emitting element disposed on the base layer and disposed in the first opening; and
a light sensing element disposed on the base layer and disposed in the second opening,
wherein at least a portion of the second opening is surrounded by the first opening in plan view.

17. A method for manufacturing a display panel, the method comprising:
preparing a preliminary display panel including a base layer and a pixel defining layer disposed on the base layer; and
forming a first light emitting element and a light sensing element by providing an organic material on the preliminary display panel, wherein
the pixel defining layer has a first opening and a second opening, wherein
the first opening defines a first light emitting region in which the first light emitting element is disposed,
the second opening defines a sensing region in which the light sensing element is disposed, and
at least a portion of the second opening is surrounded by the first opening in plan view.

18. The method of claim 17, wherein
the first light emitting element includes a first functional layer,
the light sensing element includes a second functional layer, and
the first functional layer and the second functional layer are formed by a same process.

19. The method of claim 18, wherein forming each of the first functional layer and the second functional layer includes providing the organic material in the second opening.

20. The method of claim 17, wherein
the pixel defining layer includes:
a first pixel defining portion adjacent to the first opening and spaced apart from the second opening; and
a second pixel defining portion disposed between the first opening and the second opening, and
a height of the second pixel defining portion is smaller than a height of the first pixel defining portion.
